(19) United States
(12) Patent Application Publication
(10) Pub. No.: US 2023/0183574 A1
(43) Pub. Date: Jun. 15, 2023

(54) LIQUID CRYSTAL COMPOSITION, LIQUID CRYSTAL CURED LAYER, OPTICAL FILM, POLARIZING PLATE, AND IMAGE DISPLAY DEVICE

(71) Applicant: FUJIFILM Corporation, Tokyo (JP)

(72) Inventors: Toshikazu SUMI, Kanagawa (JP); Tatsuya IWASAKI, Kanagawa (JP); Yuki NAKAMURA, Kanagawa (JP)

(73) Assignee: FUJIFILM Corporation, Tokyo (JP)

(21) Appl. No.: 18/166,910

(22) Filed: Feb. 9, 2023

Related U.S. Application Data
(63) Continuation of application No. PCT/JP2021/031332, filed on Aug. 26, 2021.

(30) Foreign Application Priority Data
Aug. 28, 2020 (JP) 2020-144564

(51) Int. Cl. C09K 19/34; C09K 19/54; C09K 19/20

(52) U.S. Cl. CPC C09K 19/3491; C09K 19/54; C09K 19/2028; C09K 19/3497; C09K 2019/2078; C09K 2019/205

(57) ABSTRACT

Provided is a liquid crystal composition capable of suppressing a decrease in phase transition temperature from a smectic phase to a nematic phase and suppressing alignment defects in a liquid crystal cured layer thus formed, a liquid crystal cured layer, an optical film, a polarizing plate, and an image display device. The liquid crystal composition includes a liquid crystal compound exhibiting a smectic phase and a freezing point depressant, in which the liquid crystal compound is a compound represented by Formula (I) SP1-MG-SP2, and the liquid crystal composition satisfies Expression (1) |Am−Asl≥0.2 and Expression (2-1) in a case of Am≤As, Aa≥(Am+As)/2 or Expression (2-2) in a case of Am>As, Aa≤(Am+As)/2.

### CROSS-REFERENCE TO RELATED APPLICATIONS

This application is a Continuation of PCT International Application No. PCT/JP2021/031332 filed on Aug. 26, 2021, which claims priority under 35 U.S.C. § 119(a) to Japanese Patent Application No. 2020-144564 filed on Aug. 28, 2020. The above applications are hereby expressly incorporated by reference, in its entirety, into the present application.

### BACKGROUND OF THE INVENTION

### 1. Field of the Invention

The present invention relates to a liquid crystal composition, a liquid crystal cured layer, an optical film, a polarizing plate, and an image display device.

### 2. Description of the Related Art

Optical films such as an optical compensation sheet and a phase difference film are used in various image display devices in order to eliminate image coloration or expand a viewing angle.

A stretched birefringent film has been used as the optical film, but in recent years, it has been proposed to use an optical film having an optically anisotropic layer consisting of a liquid crystal compound instead of the stretched birefringent film.

As a composition for forming such an optically anisotropic layer, for example, a polymerizable composition including one or more kinds of polymerizable rod-like liquid crystal compounds exhibiting a smectic phase is described in JP2015-200861A ([Claim 1] [0048]), and it is also described that a non-liquid crystalline polyfunctional polymerizable compound is blended as an optional component ([0050]).

In addition, a composition including a liquid crystal compound exhibiting a smectic phase and a non-liquid crystal compound satisfying a predetermined condition is described in JP2016-051178A ([0022] and [0023]).

### SUMMARY OF THE INVENTION

The present inventors have conducted studies on the compositions described in JP2015-200861A and JP2016-051178A, and have clarified that in a case where an additive (for example, a non-liquid crystal compound) is blended with a liquid crystal compound from the viewpoints of, for example, suppression of crystallization, a phase transition temperature from a smectic phase to a nematic phase is lowered, depending on the type of the additive, and alignment defects occur in a liquid crystal cured layer (for example, an optically anisotropic layer) thus formed.

Therefore, an object of the present invention is to provide a liquid crystal composition capable of suppressing a decrease in phase transition temperature from a smectic phase to a nematic phase and suppressing alignment defects in a liquid crystal cured layer thus formed, a liquid crystal cured layer, an optical film, a polarizing plate, and an image display device.

The present inventors have conducted intensive studies in order to accomplish the object, and as a result, they have found that by setting I/O values of a liquid crystal compound exhibiting a smectic phase and a freezing point depressant to satisfy a predetermined relationship in a liquid crystal composition containing the liquid crystal compound and the freezing point depressant, a decrease in phase transition temperature from a smectic phase to a nematic phase is suppressed and alignment defects in a liquid crystal cured layer thus formed are suppressed, thereby completing the present invention.

That is, the present inventors have found that it is possible to accomplish the object by the following configurations.
[1] A liquid crystal composition comprising:
   a liquid crystal compound exhibiting a smectic phase; and
   a freezing point depressant,
   in which the liquid crystal compound is a compound represented by Formula (I), and
   the liquid crystal composition satisfies Expression (1) and Expression (2-1) or (2-2).

SP1-MG-SP2 (I)
Here, in Formula (I),
SP1 and SP2 each independently represent a spacer group.
MG represents a mesogen group.

|Am−As|≥0.2 (1)

In a case of Am≤As,Aa≥(Am+As)/2 (2-1)

In a case of Am>As,Aa≤(Am+As)/2 (2-2)
Here, in Expressions (1), (2-1), and (2-2),
Am represents an I/O value of the mesogen group of the liquid crystal compound.
As represents an I/O value of the spacer group of the liquid crystal compound. It should be noted that in a case where structures of SP1 and SP2 in Formula (I) are different from each other, with Am≤As, As represents an I/O value of a spacer group having a larger I/O value, and with Am>As, As represents an I/O value of a spacer group having a smaller I/O value.
Aa represents an I/O value of the freezing point depressant.
[2] The liquid crystal composition as described in [1], in which the freezing point depressant is a non-liquid crystal compound.
[3] The liquid crystal composition as described in [1] or [2], in which a content of the freezing point depressant is 1 to 30 parts by mass with respect to 100 parts by mass of the liquid crystal compound.
[4] The liquid crystal composition as described in any one of [1] to [3],
in which the freezing point depressant has a molecular weight of 2,000 or less.
[5] The liquid crystal composition as described in any one of [I] to [4],
in which the freezing point depressant has a polymerizable group.
[6] The liquid crystal composition as described in any one of [I] to [5],
in which a molar absorption coefficient of the freezing point depressant at a wavelength of 350 to 750 nm is 100 (1/mol·cm) or less.
[7] The liquid crystal composition as described in any one of [1] to [6],
in which an optically anisotropic layer manufactured using the liquid crystal compound satisfies Expression (3).

Re(450)/Re(550)>1.0 (3)

Here, in Expression (3), Re(450) represents an in-plane retardation of the optically anisotropic layer at a wavelength of 450 nm and Re(550) represents an in-plane retardation of the optically anisotropic layer at a wavelength of 550 nm.
[8] The liquid crystal composition as described in any one of [1] to [6],
in which an optically anisotropic layer manufactured using the liquid crystal compound satisfies Expression (4).

Re(450)/Re(550)<1.0 (4)

Here, in Expression (4), Re(450) represents an in-plane retardation of the optically anisotropic layer at a wavelength of 450 nm and Re(550) represents an in-plane retardation of the optically anisotropic layer at a wavelength of 550 nm.
[9] The liquid crystal composition as described in any one of [1] to [8],
in which the liquid crystal compound is a compound represented by Formula (I) which will be described later.

[10] The liquid crystal composition as described in [9],
in which Ar in Formula (II) which will be described later represents any aromatic ring selected from the group consisting of groups represented by Formulae (Ar-1) to (Ar-7) which will be described later.

The liquid crystal composition as described in any one of [1] to [10], further comprising a dichroic substance.
[12] A liquid crystal cured layer obtained by immobilizing an alignment state of the liquid crystal composition as described in any one of [1] to [11].
[13] The liquid crystal cured layer as described in [12],
in which the optically anisotropic layer exhibits a diffraction peak derived from a periodic structure in X-ray diffraction measurement.
[14] The liquid crystal cured layer as described in [12] or [13],
in which the liquid crystal compound included in the polymerizable liquid crystal composition is immobilized in a state of being horizontally aligned with respect to a main surface of the optically anisotropic layer.
[15] The liquid crystal cured layer as described in any one of [12] to [14],
in which the liquid crystal cured layer is a positive A plate.
[16] The liquid crystal cured layer as described in any one of [12] to [14],
which the liquid crystal cured layer is a polarizer.
[17] An optical film comprising the liquid crystal cured layer in any one of [12] to [16].
[18] The optical film as described in [17],
in which the liquid crystal cured layer is formed on a surface of a photo-alignment film.
[19] A polarizing plate comprising:
a liquid crystal cured layer obtained by immobilizing an alignment state of the liquid crystal composition as described in any one of [1] to [10]; and
a polarizer.
[20] A polarizing plate comprising:
a phase difference film; and
a liquid crystal cured layer obtained by immobilizing an alignment state of the liquid crystal composition as described in [11].
[21] A polarizing plate comprising:
a liquid crystal cured layer obtained by immobilizing an alignment state of the liquid crystal composition as described in any one of [1] to [10]; and
a liquid crystal cured layer obtained by immobilizing an alignment state of the liquid crystal composition as described in [11].
[22] An image display device comprising:
the optical film as described in [17] or [18], or the polarizing plate as described in any one of [19] to [21].
[23] The image display device as described in [22],
in which the image display device is a liquid crystal display device.
[24] The image display device as described in [22],
in which the image display device is an organic EL display device.
[25] A method for suppressing crystallization while suppressing a decrease in phase transition temperature of a liquid crystal compound exhibiting smectic properties from a smectic phase to a nematic phase, by mixing the liquid crystal compound with a freezing point depressant,
in which the liquid crystal compound is a compound represented by Formula (I), and
the freezing point depressant is mixed with the liquid crystal compound to satisfy Expression (1) and Expression (2-1) or (2-2).

SP1-MG-SP2 (I)
Here, in Formula (I),
SP1 and SP2 each independently represent a spacer group.
MG represents a mesogen group.

|Am−As|≥0.2 (1)

In a case of Am≤As,Aa≥(Am+As)/2 (2-1)

In a case of Am>As,Aa≤(Am+As)/2 (2-2)

Here, in Expressions (1), (2-1), and (2-2),

Am represents an I/O value of the mesogen group of the liquid crystal compound.

As represents an I/O value of the spacer group of the liquid crystal compound. It should be noted that in a case where structures of SP1 and SP2 in Formula (I) are different from each other, with Am≤As, As represents an I/O value of a spacer group having a larger I/O value, and with Am>As, As represents an I/O value of a spacer group having a smaller I/O value.

Aa represents an I/O value of the freezing point depressant.

According to the present invention, it is possible to provide a liquid crystal composition capable of suppressing a decrease in phase transition temperature from a smectic phase to a nematic phase and suppressing alignment defects in a liquid crystal cured layer thus formed, a liquid crystal cured layer, an optical film, a polarizing plate, and an image display device.

### BRIEF DESCRIPTION OF THE DRAWINGS

FIG. 1 is a schematic cross-sectional view showing an example of the optical film.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

Furthermore, in the present specification, a numerical value range expressed using “to” means a range that includes the preceding and succeeding numerical values of “to” as the lower limit value and the upper limit value, respectively.

In addition, in the present specification, only one kind of the substance corresponding to each component may be used alone or two or more kinds thereof may also be used in combination, for each component. Here, in a case where the two or more kinds of substances are used in combination for each component, the content of the component refers to a total content of the substances used in combination unless otherwise specified.

Moreover, in the present specification, the bonding direction of a divalent group (for example, —CO—O—) as noted is not particularly limited unless the bonding position is specified, and for example, in a case where D¹ in Formula (II) which will be described later is —CO—NR—, D¹ may be either *1-CO—NR—*2 or *1-NR—CO—**2, in which *1 represents a bonding position to the G¹ side and *2 represents a bonding position to the Ar side.

[Liquid Crystal Composition]

The liquid crystal composition of an embodiment of the present invention is a liquid crystal composition including a liquid crystal compound exhibiting a smectic phase and a freezing point depressant, in which the liquid crystal compound is a compound represented by Formula (I), and the liquid crystal composition satisfies Expression (1) and Expression (2-1) or (2-2).

Furthermore, in a case where the liquid crystal composition of the embodiment of the present invention contains two or more kinds of liquid crystal compounds exhibiting a smectic phase, the liquid crystal composition may satisfy Expression (1) and Expression (2-1) or (2-2) in terms of a relationship with any one kind of liquid crystal compound.

Similarly, in a case where the liquid crystal composition of the embodiment of the present invention contains two or more kinds of freezing point depressants, the liquid crystal composition may satisfy Expression (1) and Expression (2-1) or (2-2) in relationship to any one of freezing point depressants.

SP1-MG-SP2 (I)

Here, in Formula (I),

SP1 and SP2 each independently represent a spacer group.

MG represents a mesogen group.

|Am−As|≥0.2 (1)

In a case of Am≤As,Aa≥(Am+As)/2 (2-1)

In a case of Am>As,Aa≤(Am+As)/2 (2-2)

Here, in Expressions (1), (2-1), and (2-2),

Am represents an I/O value of the mesogen group of the liquid crystal compound.

As represents an I/O value of the spacer group of the liquid crystal compound. It should be noted that in a case where structures of SP1 and SP2 in Formula (I) are different from each other, with Am≤As, As represents an I/O value of a spacer group having a larger I/O value, and with Am>As, As represents an I/O value of a spacer group having a smaller I/O value.

Aa represents an I/O value of the freezing point depressant.

Here, the “I/O value” is used as one unit for predicting various physicochemical properties of an organic compound. The magnitude of organicity is obtained by comparison of the number of carbon atoms and the magnitude of inorganicity is obtained by comparison of the boiling points of the same number of hydrocarbons as the number of carbon atoms. For example, the organicity value of one (—CH₂—) (actually C) is determined as 20 and the inorganicity value is determined as 100 from an influence of a hydroxyl group (—OH) on the boiling point. Based on the inorganicity value of (—OH) of 100, values of other substituents (inorganic groups) arc obtained, which is shown as an “inorganic group table”. According to the inorganic group table, the ratio I/O of inorganicity (I) value and organicity (0) value obtained for each molecule is defined as “I/O value”. It is shown that the larger the I/O value, the higher the hydrophilicity thereof, and the smaller the I/O value, the stronger the hydrophobicity.

In the present invention, the “I/O value” is a value of “inorganicity (I)/organicity (O)” obtained by a method described in “YOSHIO KOUDA et al., “New edition Organic Conceptual Diagram Foundation and Application”, November 2008, SANKYO PUBLISHING”.

In the present invention, the liquid crystal compound is the compound represented by Formula (I), and by allowing the liquid crystal composition containing the liquid crystal compound and a freezing point depressant to satisfy Expression (1) and Expression (2-1) or (2-2), a decrease in phase transition temperature from a smectic phase to a nematic phase is suppressed and alignment defects in a liquid crystal cured layer thus formed are suppressed.

A reason thereof is not specifically clear, but is presumed to be as follows by the present inventors.

First, it can be said that the liquid crystal compound is the compound represented by Formula (I), in which the mesogen group and the spacer group are difficult to be compatible with each other by satisfying Expression (1).

In addition, it can be said that the freezing point depressant is easily compatible with the spacer group than the mesogen group in the liquid crystal compound by satisfying Expression (2-1) or (2-2).

Therefore, in the present invention, it is considered that the freezing point depressant suppresses crystallization by not inhibiting the packing among the mesogen groups in the liquid crystal compound required for the expression of the smectic phase, but inhibiting the arrangement of the spacer portion in the liquid crystal compound. Further, it is considered that such an action of the freezing point depressant makes it possible to stably lower the aging temperature of the liquid crystal layer before curing to a low temperature, and as a result, the alignment defects in a liquid crystal cured layer thus formed can be suppressed.

Hereinafter, the respective components of the liquid crystal composition of the embodiment of the present invention will be described in detail.

[Liquid Crystal Compound]

The liquid crystal compound contained in the liquid crystal composition of the embodiment of the present invention is a liquid crystal compound exhibiting smectic properties.

Here, the smectic phase exhibited by the liquid crystal compound refers to a state in which molecules aligned in one direction have a layered structure.

In addition, the smectic phase is not particularly limited, but is preferably a higher-order smectic phase. The higher-order smectic phase as mentioned herein is a smectic A phase, a smectic B phase, a smectic D phase, a smectic E phase, a smectic F phase, a smectic G phase, a smectic H phase, a smectic I phase, a smectic J phase, a smectic K phase, and a smectic L phase, and among these, the smectic A phase, the smectic B phase, the smectic F phase, the smectic I phase, the slanted smectic F phase, and the slanted smectic I phase are more preferable, and the smectic A phase and the smectic B phase are particularly preferable.

In addition, the liquid crystal compound contained in the liquid crystal composition of the embodiment of the present invention is a compound represented by Formula (I).

SP1-MG-SP2 (I)

In Formula (I), SP1 and SP2 each independently represent a spacer group.

In addition, in Formula (I), MG represents a mesogen group.

Here, the mesogen group is a group exhibiting a main skeleton of a liquid crystal molecule that contributes to the formation of a liquid crystal, and is a group consisting of portions having continuous ring structures.

The mesogen group is not particularly limited, and reference can be made to, for example, “Flussige Kristalle in Tabellen II” (VEB Deutsche Verlag fur Grundstoff Industrie, Leipzig, published in 1984), particularly the descriptions on pages 7 to 16, and Editorial committee of Liquid Crystal Handbook, liquid crystal handbook (Maruzen Publishing Co., Ltd., published in 2000), particularly the descriptions in Chapter 3.

As the mesogen group, for example, a group having at least one kind of cyclic structure selected from the group consisting of an aromatic hydrocarbon group, a heterocyclic group, and an alicyclic group is preferable.

In addition, the spacer group has a structure other than the mesogen group included in the liquid crystal compound, and refers to a group from the first of the ring structure constituting the mesogen group to the terminal of the molecule.

Further, in the liquid crystal compound contained in the liquid crystal composition of the embodiment of the present invention is a compound having an absolute value of the difference between the I/O value of the mesogen group and the I/O value of the spacer group of 0.2 or more, and preferably 0.2 to 2.0, as represented by Expression (1).

Here, the definition of the I/O value is as described above, but in the calculation of the I/O value of the mesogen group and the I/O value of the spacer group in the liquid crystal compound, a bonding part located in the boundary between the mesogen group and the spacer group is considered to be included in any of the mesogen group and the spacer group for the calculation. For example, for the liquid crystal compound represented by Formula (L-1), the I/O values are calculated with a mesogen group represented by Formula (mL-1) and a spacer group represented by Formula (sL-1).

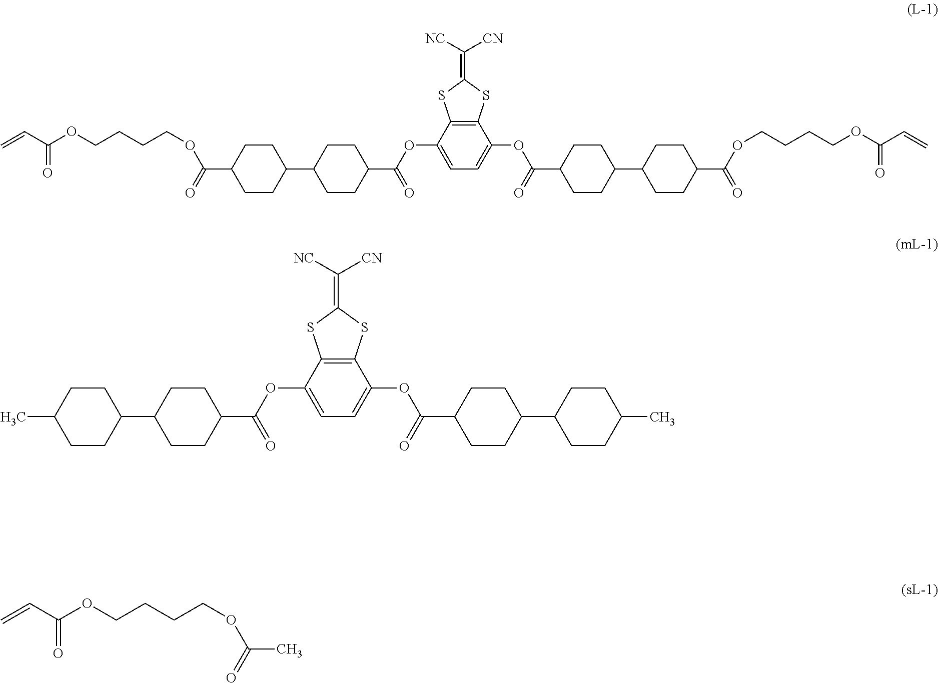

In the present invention, it is preferable that an optically anisotropic layer manufactured using the liquid crystal compound satisfies Expression (3) for a reason that the liquid crystal alignment properties of a liquid crystal cured layer thus manufactured are improved.

Re(450)/Re(550)>1.0 (3)

Here, in Expression (3), Re(450) represents an in-plane retardation of the optically anisotropic layer at a wavelength of 450 nm and Re(550) represents an in-plane retardation of the optically anisotropic layer at a wavelength of 550 nm.

In addition, the value of the in-plane retardation refers to a value measured with light at the measurement wavelength using AxoScan OPMF-1 (manufactured by Opto Science, Inc.).

Specifically, by inputting an average refractive index ((Nx+Ny+Nz)/3) and a film thickness (d (μm)) to AxoScan OPMF-1, it is possible to calculate:

Slow axis direction)(°)

Re(λ)=R0(λ)

Rth(λ)=((nx+ny)/2−nz)×d.

In addition, R0(λ) is expressed in a numerical value calculated with AxoScan OPMF-1, but means Re(λ).

In addition, as the optically anisotropic layer to be measured of the in-plane retardation, that is, an optically anisotropic layer manufactured using the liquid crystal compound, an optically anisotropic layer manufactured by the following procedure is used.

That is, a liquid crystal composition L having the following composition is applied onto a glass substrate including a rubbing-treated polyimide alignment film (SE-150 manufactured by Nissan Chemical Industries, Ltd.) by spin coating.

Then, the coating film is heated and aligned at a temperature at which liquid crystallinity is exhibited, thereby forming a liquid crystal layer.

Next, the liquid crystal layer is cooled to a temperature that is 40° C. lower than the temperature at which liquid crystallinity is exhibited, the alignment is immobilized by irradiation with ultraviolet rays of 1,000 mJ/cm², thereby manufacturing an optically anisotropic film.

Liquid crystal composition L

| | |
|---|---|
| Liquid crystal compound | 15.00 parts by mass |
| Photopolymerization initiator | 0.45 parts by mass |
| (Irgacure 819, manufactured by BASF) | |
| The following fluorine-containing compound A | 0.12 parts by mass |
| Chloroform | 35.00 parts by mass |

Fluorine-Containing Compound a

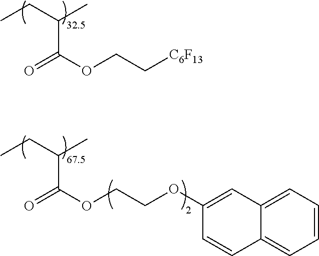

In the present invention, it is preferable that an optically anisotropic layer manufactured using the liquid crystal compound satisfies Formula (4) for a reason that the optical compensatory properties of a liquid crystal cured layer (in particular, the optically anisotropic layer) thus manufactured are further improved. Furthermore, as the optically anisotropic layer to be measured for the in-plane retardation, an optically anisotropic layer manufactured by the above-mentioned procedure is used.

Re(450)/Re(550)≤1.0 (4)

Here, in Expression (4), Re(450) represents an in-plane retardation of the optically anisotropic layer at a wavelength of 450 nm and Re(550) represents an in-plane retardation of the optically anisotropic layer at a wavelength of 550 nm.

In the present invention, it is preferable that the liquid crystal compound is a compound represented by Formula (II) for a reason that the liquid crystal alignment properties with a liquid crystal cured layer thus manufactured are improved.

P¹-L¹-D⁵-(A¹)ₐ₁-D³-(G¹)_{g1}-D¹-[Ar-D²]_{q1}-(G²)_{g2}-D⁴-(A²)ₐ₂-D⁶- L²-P² (II)

In Formula (II), a1, a2, g1, and g2 each independently represent 0 or 1. It should be noted that at least one of a1 or g1 represents 1, and at least one of a2 or g2 represents 1.

In addition, in Formula (II), q1 represents 1 or 2.

Moreover, in Formula (II), D¹, D², D³, D⁴, D⁵, and D⁶ each independently represent a single bond; —CO—, —O—, —S—, —C(═S)—, —CR¹R²—, —CR³═CR⁴—, —NR⁵—, or a divalent linking group consisting of a combination of two or more of these groups, and R¹ to R⁵ each independently represent a hydrogen atom, a fluorine atom, or an alkyl group having 1 to 12 carbon atoms. It should be noted that in a case where q¹ is 2, a plurality of D²' s may be the same as or different from each other.

In addition, in Formula (II), G¹ and G² each independently represent an aromatic ring having 6 to 20 carbon atoms, which may have a substituent, or a divalent alicyclic hydrocarbon group having 5 to 20 carbon atoms, which may have a substituent, where one or more of —CH₂—'s constituting the alicyclic hydrocarbon group may be substituted with —O—, —S—, or —NH—.

In addition, in Formula (II), A¹ and A² each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be substituted with —O—, —S—, or —NH—.

Furthermore, in Formula (II), L¹ and L² each independently represent a single bond, a linear or branched alkylene group having 1 to 14 carbon atoms, or a divalent linking group in which one or more of —CH₂-'s constituting the linear or branched alkylene group having 1 to 14 carbon atoms are substituted with —O—, —S—, —NH—, —N(Q)-, or —CO—, where Q represents a substituent.

In addition, in Formula (II), P¹ and P² each independently represent a monovalent organic group, and at least one of P¹ or P² represents a polymerizable group. It should be noted that in a case where Ar is an aromatic ring represented by Formula (Ar-3), at least one of P¹ or P², or P³ or P⁴ in Formula (Ar-3) represents a polymerizable group.

In addition, in Formula (II), Ar represents an aromatic ring having 6 to 20 carbon atoms, which may have a substituent, or a divalent alicyclic hydrocarbon group having 5 to 20 carbon atoms, which may have a substituent, where one or more of —CH₂—'s constituting the alicyclic hydrocarbon group may be substituted with —O—, —S—, or —NH—. It should be noted that in a case where q¹ is 2, a plurality of Ar's may be the same as or different from each other.

In Formula (II), it is preferable that any of a1, a2, g1, and g2 is 1 for a reason that the liquid crystal composition of the embodiment of the present invention easily exhibits a liquid crystal state of a smectic phase.

In addition, it is preferable that both of a1 and a2 are 0 and both of g1 and g2 are 1 for a reason that the durability of a liquid crystal cured layer thus manufactured is improved.

In Formula (II), q¹ is preferably 1.

In Formula (II), examples of the divalent linking group shown in one aspect of D¹, D², D³, D⁴, D⁵, and D⁶ include —CO—, —O—, —CO—O—, —C(═S)O—, —CR¹R²—, —CR¹R²—CR¹R²—, —O—CR¹R²—, —CR¹R²—O—CR¹R²—, —CO—O—CR¹R²—, —O—CO—CR¹R²—, —CR¹R²—O—CO—CR¹R²—, —CR¹R²—CO—O—CR¹R²—, —NR⁵—CR¹R²—, and —CO—NR⁵—. R¹, R², and R⁵ each independently represent a hydrogen atom, a fluorine atom, or an alkyl group having 1 to 12 carbon atoms.

Among these, any of —CO—, —O—, and —CO—O— is preferable.

In Formula (II), examples of the aromatic ring having 6 to 20 carbon atoms, shown in one aspect of G¹ and G², include an aromatic hydrocarbon ring such as a benzene ring, a naphthalene ring, an anthracene ring, and a phenanthroline ring; and an aromatic heterocyclic ring such as a furan ring, a pyrrole ring, a thiophene ring, a pyridine ring, a thiazole ring, and a benzothiazole ring. Among those, the benzene ring (for example, a 1,4-phenyl group) is preferable.

In Formula (II), the divalent alicyclic hydrocarbon group having 5 to 20 carbon atoms, shown in one aspect of G¹ and G², is preferably a 5- or 6-membered ring. In addition, the alicyclic hydrocarbon group may be saturated or unsaturated, but is preferably a saturated alicyclic hydrocarbon group. With regard to the divalent alicyclic hydrocarbon group represented by each of G¹ and G², reference can be made to, for example, the description in paragraph [0078] of JP2012-21068A, the contents of which are hereby incorporated by reference.

In the present invention, G¹ and G² in Formula (II) are each preferably a cycloalkane ring for a reason that the durability of a liquid crystal cured layer thus manufactured is improved.

Specific examples of the cycloalkane ring include a cyclohexane ring, a cyclopeptane ring, a cyclooctane ring, a cyclododecane ring, and a cyclodocosane ring.

Among those, the cyclohexane ring is preferable, a 1,4-cyclohexylene group is more preferable, and a trans-1,4-cyclohexylene group is still more preferable.

In addition, in G¹ and G² in Formula (II), examples of a substituent which may be contained in the aromatic ring having 6 to 20 carbon atoms or the divalent alicyclic hydrocarbon group having 5 to 20 carbon atoms include an alkyl group, an alkoxy group, an alkylcarbonyl group, an alkoxycarbonyl group, an alkylcarbonyloxy group, an alkylamino group, a dialkylamino group, an alkylamide group, an alkenyl group, an alkynyl group, a halogen atom, a cyano group, a nitro group, an alkylthiol group, and an N-alkylcarbamate group, and among these, the alkyl group, the alkoxy group, the alkoxycarbonyl group, the alkylcarbonyloxy group, or the halogen atom is preferable.

As the alkyl group, a linear, branched, or cyclic alkyl group having 1 to 18 carbon atoms is preferable, an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group) is more preferable, an alkyl group having 1 to 4 carbon atoms is still more preferable, and the methyl group or the ethyl group is particularly preferable.

As the alkoxy group, an alkoxy group having 1 to 18 carbon atoms is preferable, an alkoxy group having 1 to 8 carbon atoms (for example, a methoxy group, an ethoxy group, an n-butoxy group, and a methoxyethoxy group) is more preferable, an alkoxy group having 1 to 4 carbon atoms is still more preferable, and the methoxy group or the ethoxy group is particularly preferable.

Examples of the alkoxycarbonyl group include a group in which an oxycarbonyl group (—O—CO— group) is bonded to the alkyl group exemplified above, and among these, the alkoxycarbonyl group is preferably a methoxycarbonyl group, an ethoxycarbonyl group, an n-propoxycarbonyl group, or an isopropoxycarbonyl group, and more preferably the methoxycarbonyl group.

Examples of the alkylcarbonyloxy group include a group in which a carbonyloxy group (—CO—O— group) is bonded to the alkyl group exemplified above, and among these, the alkylcarbonyloxy group is preferably a methylcarbonyloxy group, an ethylcarbonyloxy group, an n-propylcarbonyloxy group, or an isopropylcarbonyloxy group, and more preferably the methylcarbonyloxy group.

Examples of the halogen atom include a fluorine atom, a chlorine atom, a bromine atom, and an iodine atom, and among these, the fluorine atom or the chlorine atom is preferable.

In Formula (II), examples of the aromatic ring having 6 to 20 or more carbon atoms, shown in one aspect of A¹ and A², include the same ones as those described in G¹ and G² in Formula (II).

In addition, in Formula (II), examples of the divalent alicyclic hydrocarbon group having 5 to 20 carbon atoms, shown in one aspect of A¹ and A², include the same ones as those described in G¹ and G² in Formula (II).

Moreover, in A¹ and A², examples of the substituent which may be contained in the aromatic ring having 6 to 20 carbon atoms or the divalent alicyclic hydrocarbon group having 5 to 20 carbon atoms include the same ones as those of the substituent which may be contained in each of G¹ and G² in Formula (II).

Suitable examples of the linear or branched alkylene group having 1 to 14 carbon atoms, shown in one aspect of L¹ and L², in Formula (II) include a methylene group, an ethylene group, a propylene group, a butylene group, a pentylene group, a hexylene group, a methylhexylene group, and a heptylene group. Furthermore, L¹ and L² may be a divalent linking group in which one or more of —CH₂-'s constituting the linear or branched alkylene group having 1 to 14 carbon atoms are substituted with —O—, —S—, —NH—, —N(Q)-, or —CO—, and examples of the substituent represented by Q include the same ones as those of the substituent which may be contained in each of G¹ and G² in Formula (II).

In Formula (II), examples of the monovalent organic group represented by each of P and P² include an alkyl group, an aryl group, and a heteroaryl group. The alkyl group may be linear, branched, or cyclic, but is preferably linear. The number of carbon atoms of the alkyl group is preferably 1 to 30, more preferably 1 to 20, and still more preferably 1 to 10. Further, the aryl group may be a monocycle or a polycycle, but is preferably the monocycle. The number of carbon atoms of the aryl group is preferably 6 to 25, and more preferably 6 to 10. Further, the heteroaryl group may be a monocycle or a polycycle. The number of heteroatoms constituting the heteroaryl group is preferably 1 to 3. The heteroatom constituting the heteroaryl group is preferably a nitrogen atom, a sulfur atom, or an oxygen atom. The number of carbon atoms of the heteroaryl group is preferably 6 to 18, and more preferably 6 to 12. In addition, the alkyl group, the aryl group, and the heteroaryl group may be unsubstituted or have a substituent. Examples of the substituent include the same ones as those of the substituent which may be contained in each of G¹ and G² in Formula (II).

In Formula (II), the polymerizable group represented by at least one of P¹ or P² is not particularly limited, but is preferably a polymerizable group which is radically polymerizable or cationically polymerizable.

A known radically polymerizable group can be used as the radically polymerizable group, and suitable examples thereof include an acryloyloxy group or a methacryloyloxy group. In this case, it is known that the acryloyloxy group generally has a high polymerization rate, and from the viewpoint of improvement of productivity, the acryloyloxy group is preferable but the methacryloyloxy group can also be used as the polymerizable group.

A known cationically polymerizable group can be used as the cationically polymerizable group, and specific examples thereof include an alicyclic ether group, a cyclic acetal group, a cyclic lactone group, a cyclic thioether group, a spiroorthoester group, and a vinyloxy group. Among those, the alicyclic ether group or the vinyloxy group is suitable, and an epoxy group, an oxetanyl group, or the vinyloxy group is particularly preferable.

Particularly preferred examples of the polymerizable group include a polymerizable group represented by any of Formulae (P-1) to (P-20).

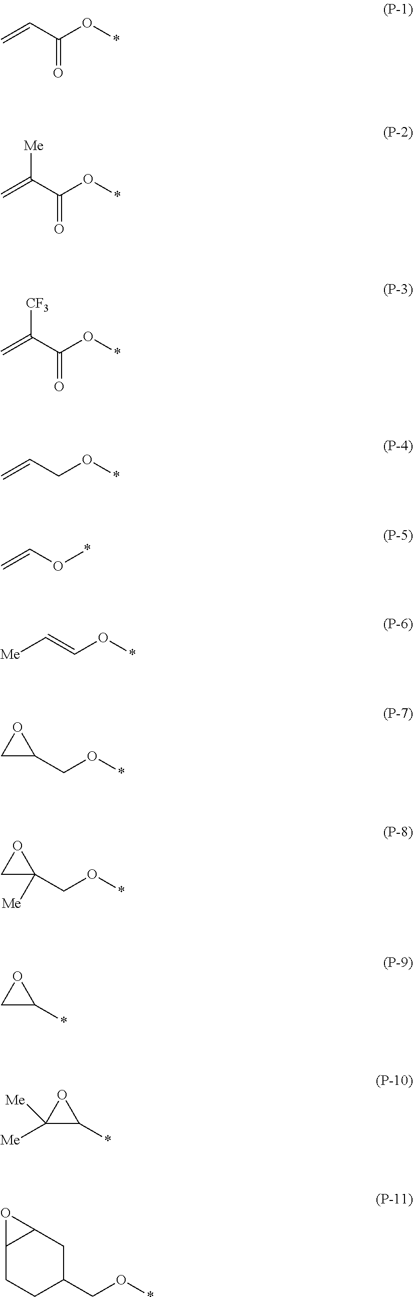

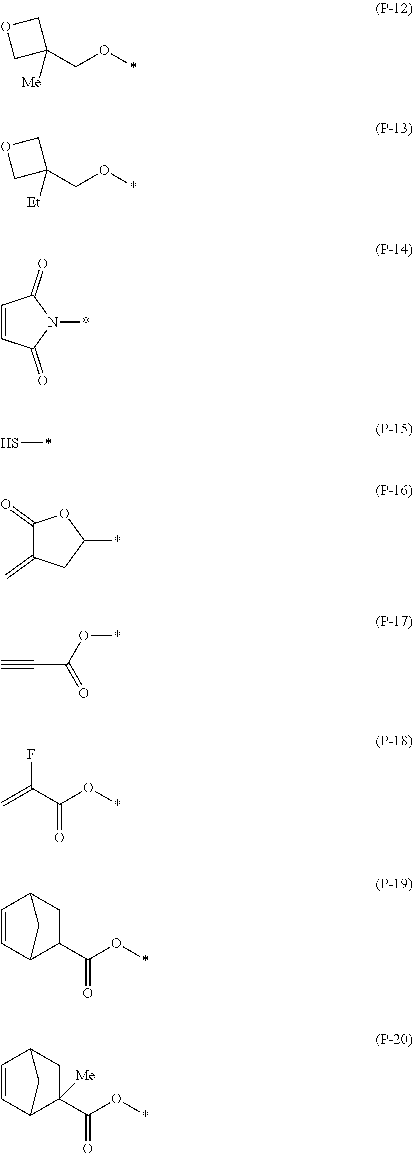

In Formula (II), any of P¹ and P² in Formula (II) is preferably a polymerizable group, and more preferably an acryloyloxy group or a methacryloyloxy group for a reason that the durability of a liquid crystal cured layer thus manufactured is improved.

On the other hand, in Formula (II), examples of the aromatic ring having 6 to 20 or more carbon atoms, shown in one aspect of Ar, include the same ones as those described in G¹ and G² in Formula (II).

In addition, in Formula (II), examples of the divalent alicyclic hydrocarbon group having 5 to 20 carbon atoms, shown in one aspect of Ar, include the same ones as those described in G¹ and G² in Formula (II).

Moreover, in Ar, examples of the substituent which may be contained in the aromatic ring having 6 to 20 carbon atoms or the divalent alicyclic hydrocarbon group having 5 to 20 carbon atoms include the same ones as those of the substituent which may be contained in each of G¹ and G² in Formula (II).

In the present invention, it is preferable that Ar in Formula (II) represents any aromatic ring selected from the group consisting of groups represented by Formulae (Ar-1) to (Ar-7) for a reason that the optical compensatory properties of a liquid crystal cured layer (in particular, an optically anisotropic layer) thus manufactured are further improved. Furthermore, in Formulae (Ar-1) to (Ar-7), * represents a bonding position to D¹ or D² in Formula (II).

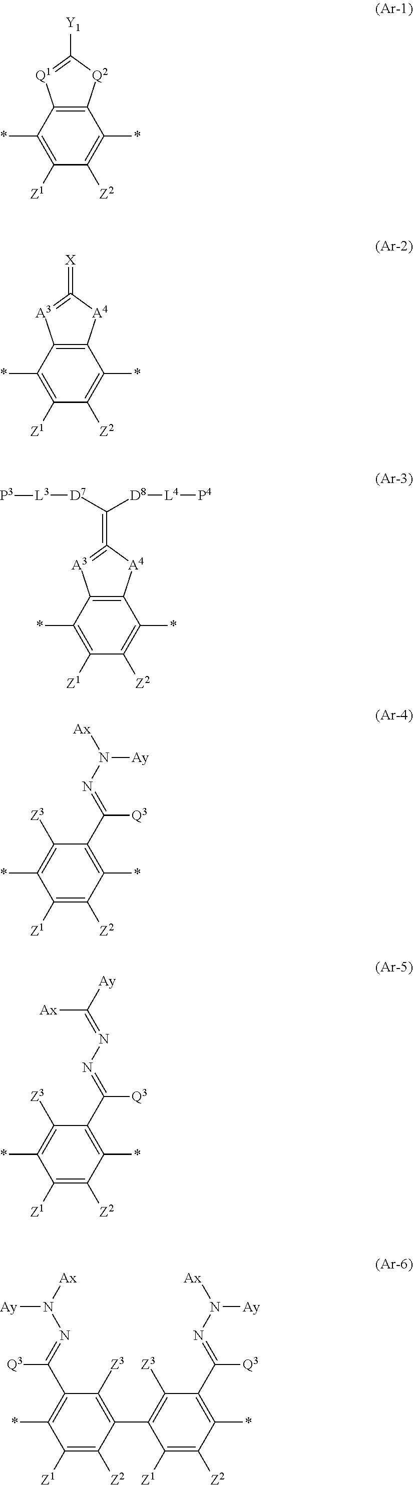

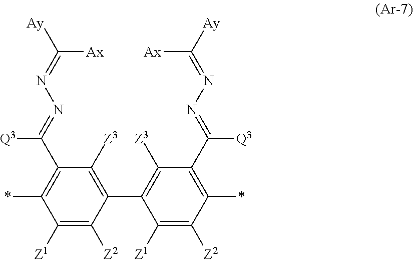

In Formula (Ar-1), Q¹ represents N or CH, Q² represents —S—, —O—, or —N(R⁶)—, R⁶ represents a hydrogen atom or an alkyl group having 1 to 6 carbon atoms, and Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, where one or more of —CH₂-'s constituting the alicyclic hydrocarbon group may be substituted with —O—, —S—, or —NH—.

Specific examples of the alkyl group having 1 to 6 carbon atoms, represented by R⁶, include a methyl group, an ethyl group, a propyl group, an isopropyl group, an n-butyl group, an isobutyl group, a sec-butyl group, a tert-butyl group, an n-pentyl group, and an n-hexyl group.

Examples of the aromatic hydrocarbon group having 6 to 12 carbon atoms, represented by Y¹, include aryl groups such as a phenyl group, a 2,6-diethylphenyl group, and a naphthyl group.

Examples of the aromatic heterocyclic group having 3 to 12 carbon atoms, represented by Y¹, include heteroaryl groups such as a thienyl group, a thiazolyl group, a furyl group, and a pyridyl group.

Examples of the alicyclic hydrocarbon group having 6 to 20 carbon atoms, represented by Y¹, include a cyclohexylene group, a cyclopentylene group, a norbornylene group, and an adamantylene group.

In addition, examples of the substituent which may be contained in Y¹ include the same ones as those of the substituent which may be contained in each of G¹ and G² in Formula (I).

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OW, —NR⁸R⁹, —SR¹⁰, —COOR¹¹, or —COR¹², where R⁷ to R¹² each independently represent a hydrogen atom or an alkyl group having 1 to 6 carbon atoms, and Z¹ and Z² may be bonded to each other to form an aromatic ring.

As the monovalent aliphatic hydrocarbon group having 1 to 20 carbon atoms, an alkyl group having 1 to 15 carbon atoms is preferable, an alkyl group having 1 to 8 carbon atoms is more preferable, and specifically a methyl group, an ethyl group, an isopropyl group, a tert-pentyl group (1,1-dimethylpropyl group), a tert-butyl group, or a 1,1-dimethyl-3,3-dimethyl-butyl group is still more preferable, and the methyl group, the ethyl group, or the tert-butyl group is particularly preferable.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and a cyclodecadiene; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Specific examples of the monovalent aromatic hydrocarbon group having 6 to 20 carbon atoms include a phenyl group, a 2,6-diethylphenyl group, a naphthyl group, and a biphenyl group, and an aryl group having 6 to 12 carbon atoms (particularly a phenyl group) is preferable.

Specific examples of the monovalent aromatic heterocyclic group having 6 to 20 carbon atoms include a 4-pyridyl group, a 2-furyl group, a 2-thienyl group, a 2-pyrimidinyl group, and a 2-benzothiazolyl group.

Examples of the halogen atom include a fluorine atom, a chlorine atom, a bromine atom, and an iodine atom, and among these, the fluorine atom, the chlorine atom, or the bromine atom is preferable.

On the other hand, specific examples of the alkyl group having 1 to 6 carbon atoms, represented by each of R⁷ to R¹⁰, include a methyl group, an ethyl group, a propyl group, an isopropyl group, an n-butyl group, an isobutyl group, a sec-butyl group, a tert-butyl group, an n-pentyl group, and an n-hexyl group.

As described above, Z¹ and Z² may be bonded to each other to form an aromatic ring, and examples of the structure in a case where Z¹ and Z² in Formula (Ar-1) are bonded to each other to form an aromatic ring include a group represented by Formula (Ar-1a). Furthermore, in Formula (Ar-1a), * represents a bonding position to D¹ or D² in Formula (I).

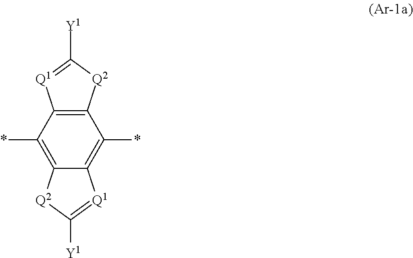

Here, in Formula (Ar-1a), examples of Q¹, Q², and Y¹ include the same ones as those described in Formula (Ar-1).

In addition, in Formulae (Ar-2) and (Ar-3), A³ and A⁴ each independently represent a group selected from the group consisting of —O—, —N(R¹³)—, —S—, and —CO—, where R¹³ represents a hydrogen atom or a substituent.

Examples of the substituent represented by 10³ include the same ones as those of the substituent which may be contained in each of G¹ and G² in Formula (II).

In addition, in Formula (Ar-2), X represents a hydrogen atom or a non-metal atom of Groups XIV to XVI, to which a substituent may be bonded.

Furthermore, examples of the non-metal atom of Groups XIV to XVI represented by X include an oxygen atom, a sulfur atom, a nitrogen atom to which a hydrogen atom or a substituent is bonded [═N—R^{N1}, R^{N1} represents a hydrogen atom or a substituent], and a carbon atom to which a hydrogen atom or a substituent is bonded [═C—(R^{C1})₂, R^{C1} represents a hydrogen atom or a substituent].

Examples of the substituent include an alkyl group, an alkoxy group, an alkyl-substituted alkoxy group, a cyclic alkyl group, an aryl group (for example, a phenyl group and a naphthyl group), a cyano group, an amino group, a nitro group, an alkylcarbonyl group, a sulfo group, and a hydroxyl group.

In addition, in Formula (Ar-3), D⁷ and D⁸ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms.

Here, specific examples of the divalent linking group include the same ones as those described in D¹, D², D³, D⁴, D⁵, and D⁶ in Formula (II).

In addition, in Formula (Ar-3), L³ and L⁴ each independently represent a single bond, a linear or branched alkylene group having 1 to 14 carbon atoms, or a divalent linking group in which one or more of —CH₂-'s constituting the linear or branched alkylene group having 1 to 14 carbon atoms are substituted with —O—, —S—, —NH—, —N(Q)-, or —CO—, where Q represents a substituent. Examples of the substituent include the same ones as those of the substituent which may be contained in each of G¹ and G² in Formula (II).

Here, examples of the alkylene group include the same ones as those described in L and L² in Formula (II).

Furthermore, in Formula (Ar-3), P³ and P⁴ each independently represent a monovalent organic group, and at least one of P³ or P⁴, or P¹ or P² in Formula (II) represents a polymerizable group.

Examples of the monovalent organic group include the same ones as those described in P¹ and P² in Formula (II).

In addition, examples of the polymerizable group include the same ones as those of the polymerizable groups described for P¹ and P² in Formula (II).

Moreover, in Formulae (Ar-4) to (Ar-7), Ax represents an organic group having 2 to 30 carbon atoms, which has at least one aromatic ring selected from the group consisting of an aromatic hydrocarbon ring and an aromatic heterocyclic ring.

In addition, in Formulae (Ar-4) to (Ar-7), Ay represents a hydrogen atom, an alkyl group having 1 to 12 carbon atoms, which may have a substituent, or an organic group having 2 to 30 carbon atoms, which has at least one aromatic ring selected from the group consisting of an aromatic hydrocarbon ring and an aromatic heterocyclic ring.

Here, the aromatic ring in each of Ax and Ay may have a substituent, and Ax and Ay may be bonded to each other to form a ring.

In addition, Q³ represents a hydrogen atom or an alkyl group having 1 to 6 carbon atoms, which may have a substituent.

Examples of each of Ax and Ay include the ones described in paragraphs [0039] to [0095] of WO2014/010325A.

In addition, specific examples of the alkyl group having 1 to 20 carbon atoms, represented by Q³, include a methyl group, an ethyl group, a propyl group, an isopropyl group, an n-butyl group, an isobutyl group, a sec-butyl group, a tert-butyl group, an n-pentyl group, and an n-hexyl group, and examples of the substituent include the same ones as those of the substituent which may be contained in each of G¹ and G² in Formula (I).

Examples of the compound represented by Formula (II) include the polymerizable compounds described in paragraphs [0019] to [0023] of JP2019-139222A; the polymerizable compounds described in paragraphs [0059] to [0061] of WO2019/160014A; the polymerizable compounds described in paragraph [0055] of WO2019/160016A; the compounds (1-1) to (1-19) represented by the following formulae; and compounds (2-1) to (2-5) represented by the following formulae. Moreover, a group adjacent to the acryloyloxy group in the structure of the compound (1-14) represents a propylene group (a group obtained by substituting a methyl group with an ethylene group), and the compound (1-14) represents a mixture of regioisomers in which the positions of the methyl groups are different.

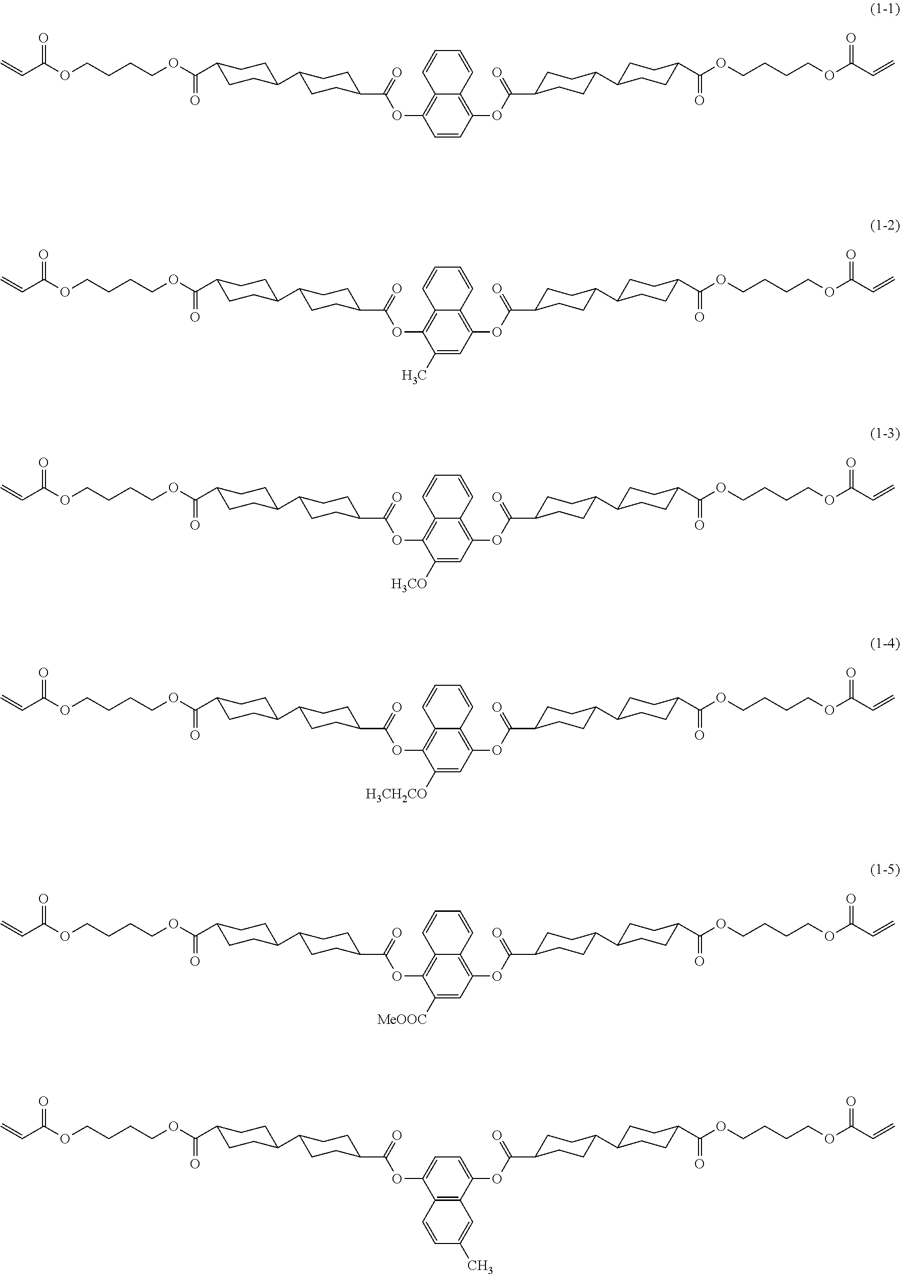

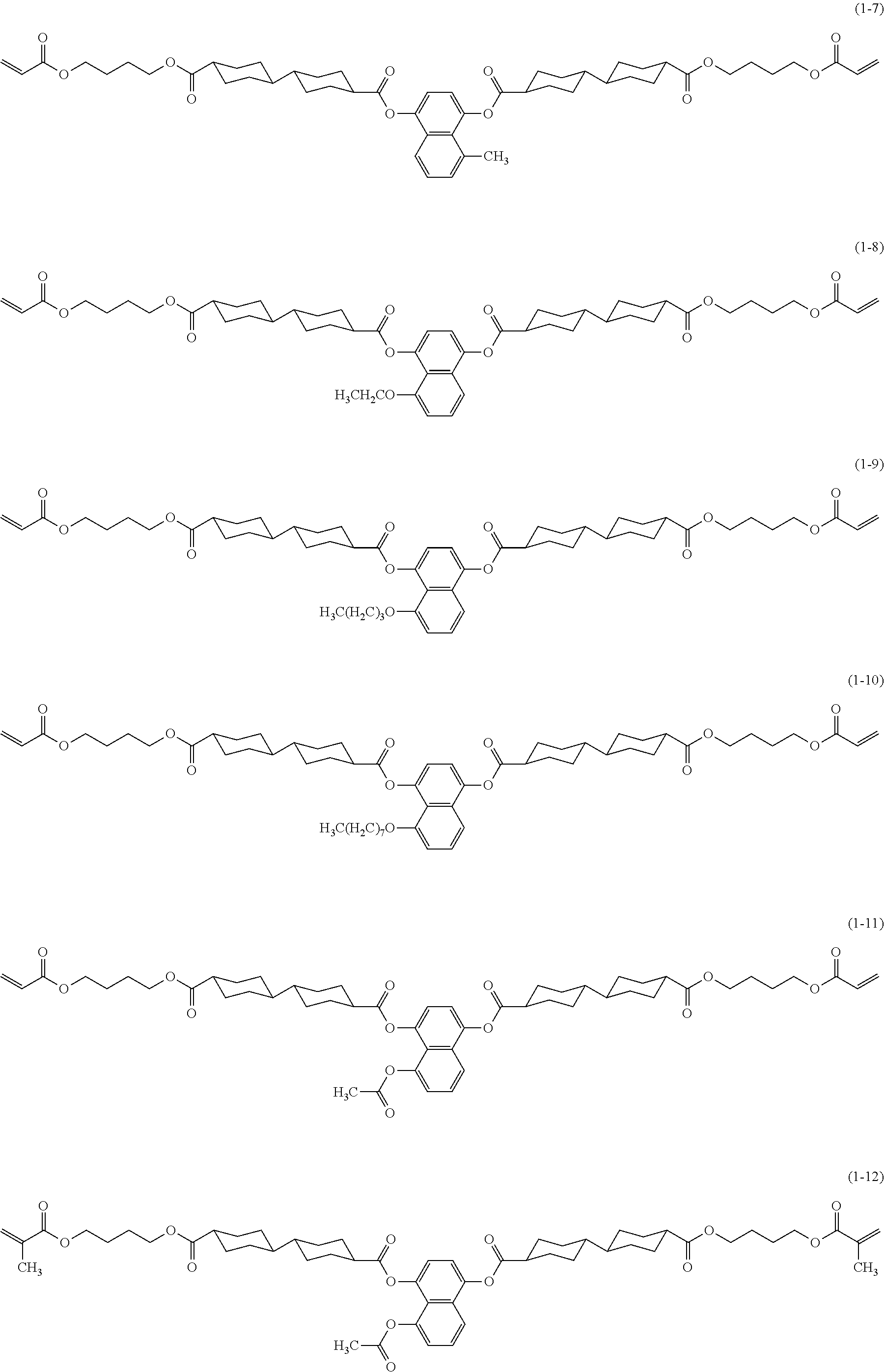

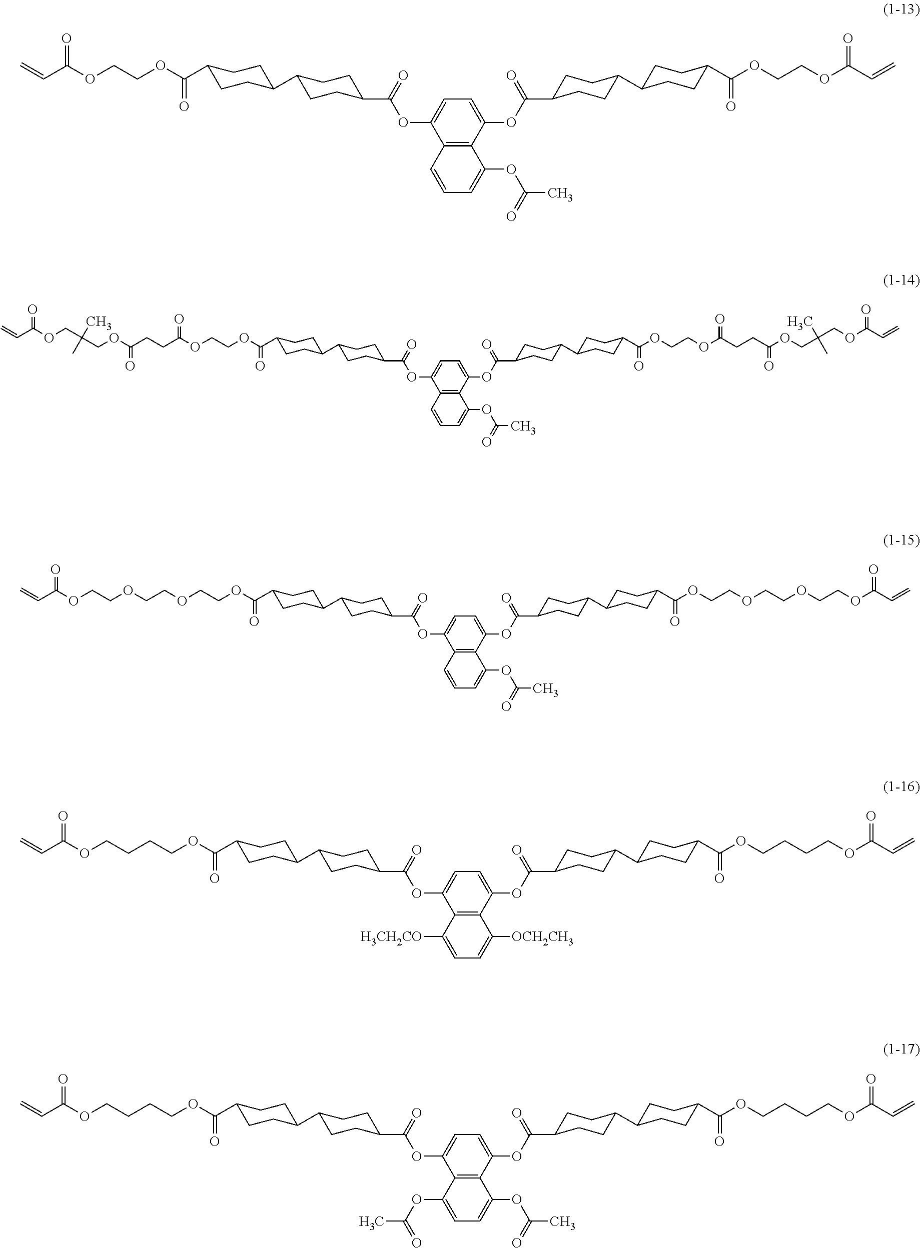

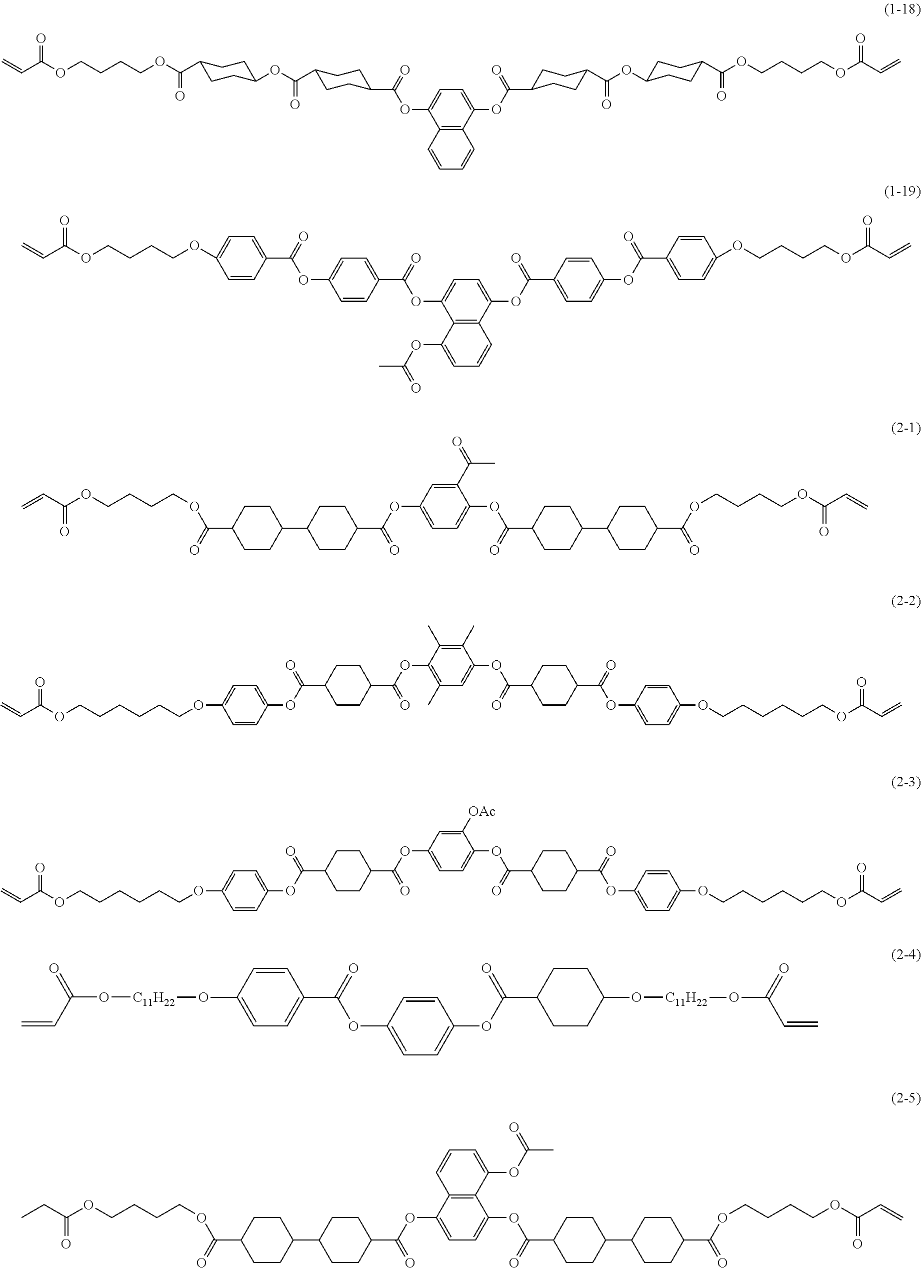

In addition, examples of the compound represented by Formula (II) include the compounds exhibiting smectic properties among the compounds represented by General Formula (1) described in JP2010-084032A (in particular, the compounds described in paragraph Nos. [0067] to [0073]), the compound represented by General Formula (II) described in JP2016-053709A (in particular, the compounds described in paragraph Nos. [0036] to [0043]), and the compounds represented by General Formula (1) described in JP2016-081035A (in particular, the compounds described in paragraph Nos. [0043] to [0055]).

Furthermore, suitable examples of the compound represented by Formula (II) include any of the compounds that exhibit smectic properties among the compounds represented by Formulae (1) to (22), and specifically include compounds having side chain structures shown in Tables 1 to 3 below as K (side chain structure) in Formulae (1) to (22).

Furthermore, in Tables 1 to 3 below, “*” shown in the side chain structure of K represents a bonding position to an aromatic ring.

In addition, in the side chain structures shown in 2-2 in Table 2 below and 3-2 in Table 3 below, a group adjacent to each of the acryloyloxy group and the methacryloyl group represents a propylene group (a group in which a methyl group is substituted with an ethylene group), and represents a mixture of regioisomers in which the positions of the methyl groups are different.

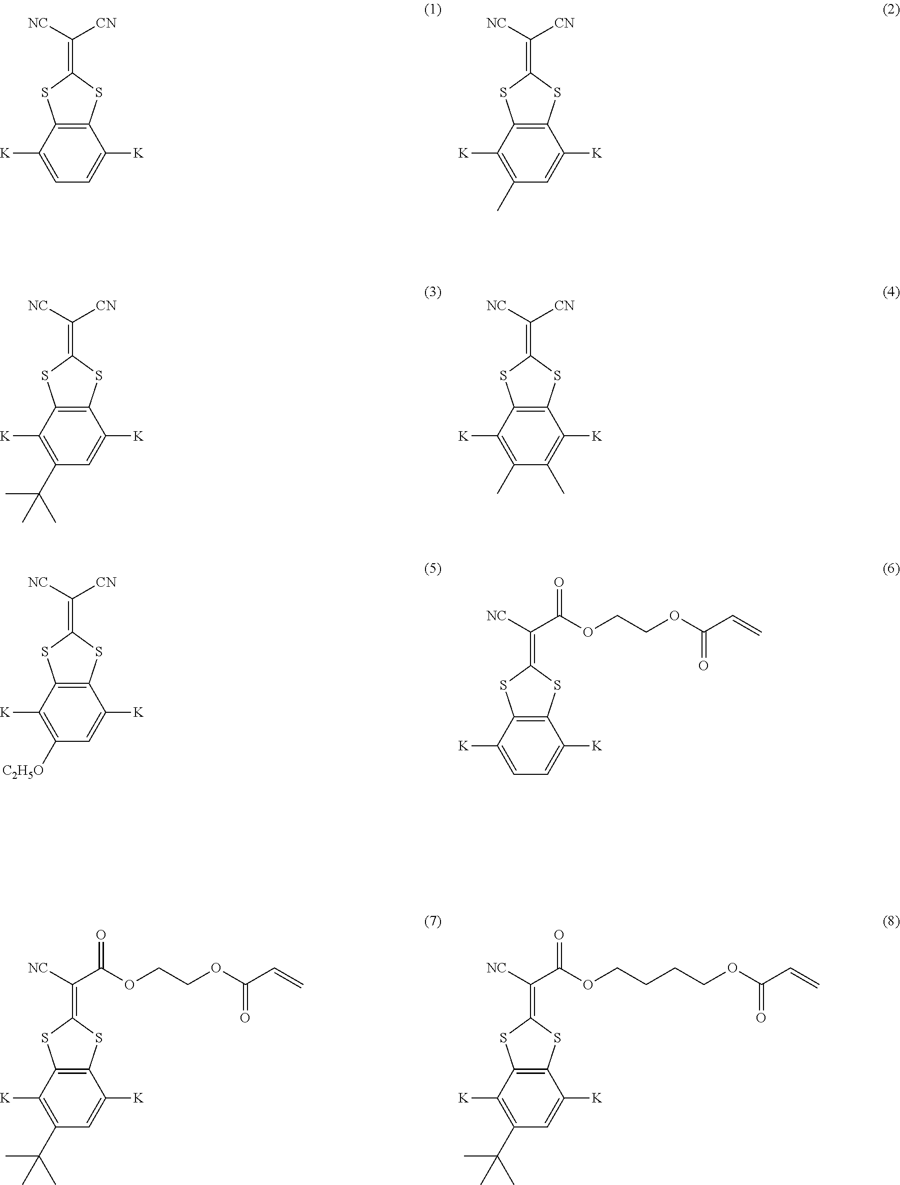

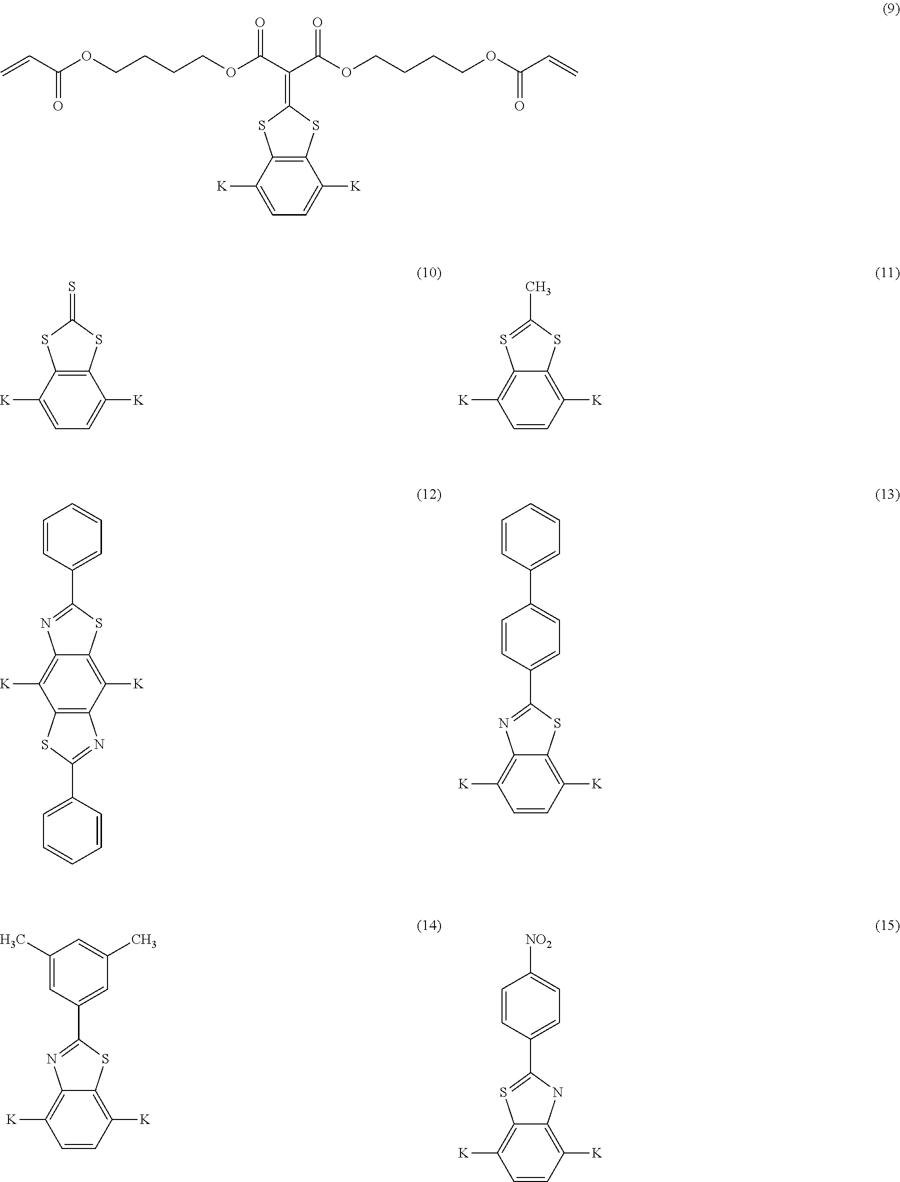

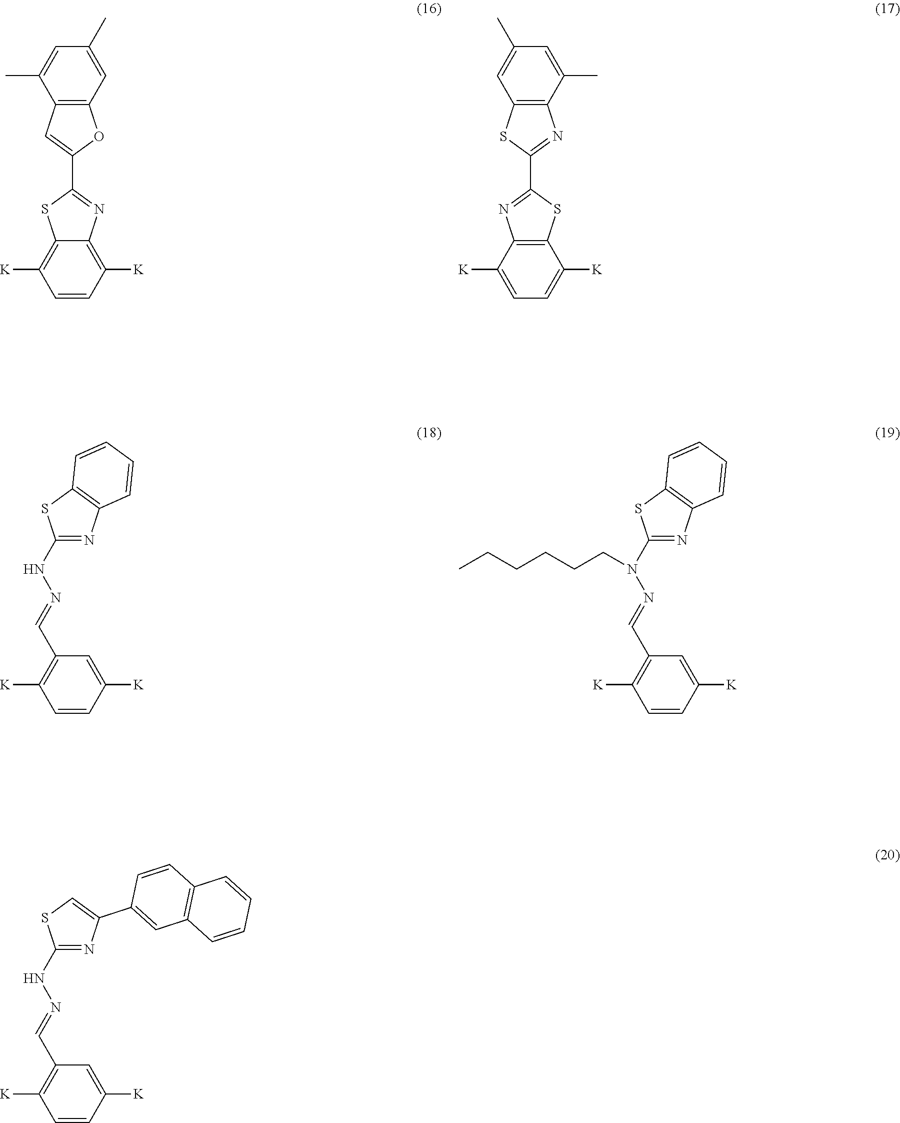

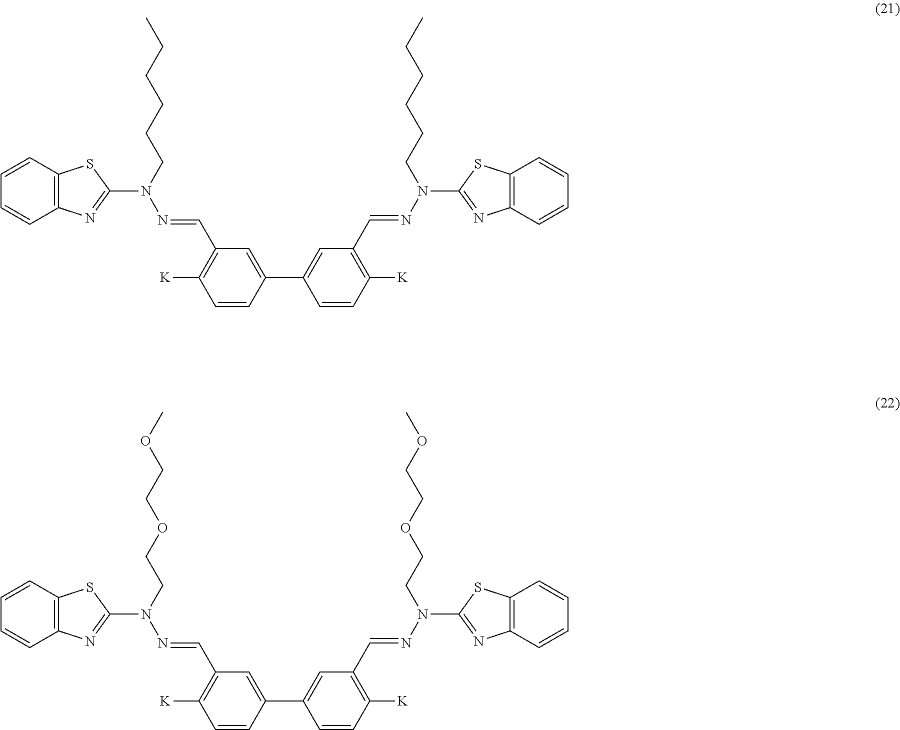

TABLE 1

| | K (side chain structure) |
|---|---|
| 1-1 | 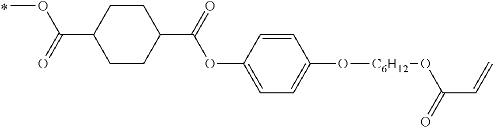 |
| 1-2 | 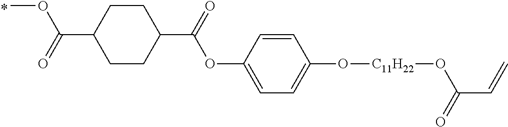 |
| 1-3 | 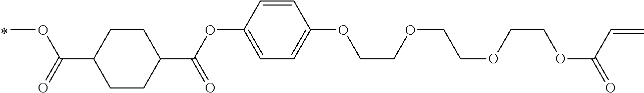 [SMILES: C=CC(=O)OCCOCCOCCOc1ccc(OC(=O)C2CCC(C(=O)OC)CC2)cc1] |
| 1-4 | 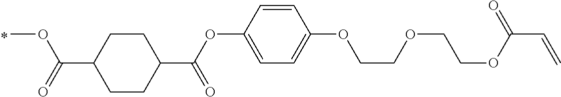 [SMILES: C=CC(=O)OCCOCCOc1ccc(OC(=O)C2CCC(C(=O)OC)CC2)cc1] |
| 1-5 | 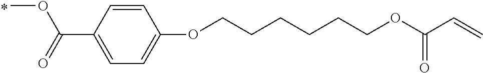 [SMILES: C=CC(=O)OCCCCCCOc1ccc(C(=O)OC)cc1] |
| 1-6 | 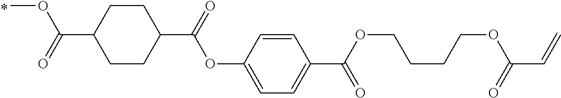 [SMILES: C=CC(=O)OCCCCOC(=O)c1ccc(OC(=O)C2CCC(C(=O)OC)CC2)cc1] |

TABLE 2

| | K (side chain structure) |
|---|---|
| 2-1 | 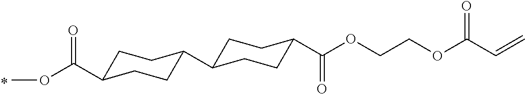 [SMILES: C=CC(=O)OCCOC(=O)C1CCC(C2CCC(C(=O)OC)CC2)CC1] |
| 2-2 | 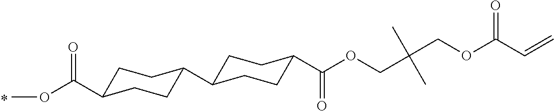 [SMILES: C=CC(=O)OCC(C)(C)COC(=O)C1CCC(C2CCC(C(=O)OC)CC2)CC1] |
| 2-3 | 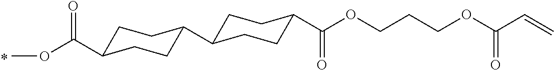 [SMILES: C=CC(=O)OCCCOC(=O)C1CCC(C2CCC(C(=O)OC)CC2)CC1] |
| 2-4 | 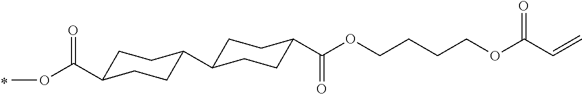 [SMILES: C=CC(=O)OCCCCOC(=O)C1CCC(C2CCC(C(=O)OC)CC2)CC1] |
| 2-5 | 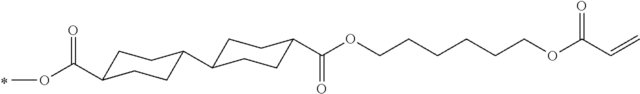 [SMILES: C=CC(=O)OCCCCCCOC(=O)C1CCC(C2CCC(C(=O)OC)CC2)CC1] |
| 2-6 | 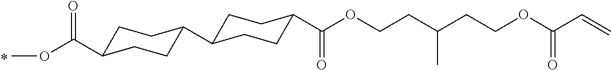 [SMILES: C=CC(=O)OCCC(C)CCOC(=O)C1CCC(C2CCC(C(=O)OC)CC2)CC1] |
| 2-7 | 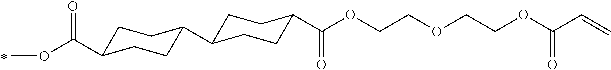 [SMILES: C=CC(=O)OCCOCCOC(=O)C1CCC(C2CCC(C(=O)OC)CC2)CC1] |
| 2-8 | 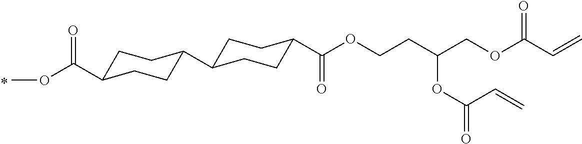 [SMILES: C=CC(=O)OCC(CCOC(=O)C1CCC(C2CCC(C(=O)OC)CC2)CC1)OC(=O)C=C] |
| 2-9 | 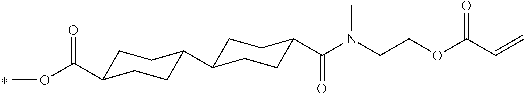 [SMILES: C=CC(=O)OCCN(C)C(=O)C1CCC(C2CCC(C(=O)OC)CC2)CC1] |
| 2-10 | 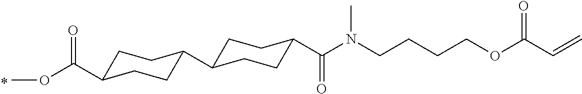 [SMILES: C=CC(=O)OCCCCN(C)C(=O)C1CCC(C2CCC(C(=O)OC)CC2)CC1] |
| 2-11 | 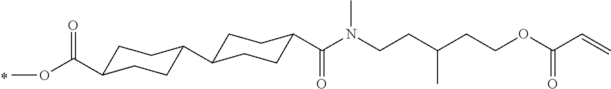 [SMILES: C=CC(=O)OCCC(C)CCN(C)C(=O)C1CCC(C2CCC(C(=O)OC)CC2)CC1] |
| 2-12 | 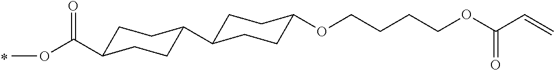 [SMILES: C=CC(=O)OCCCCOC1CCC(C2CCC(C(=O)OC)CC2)CC1] |
| 2-13 | 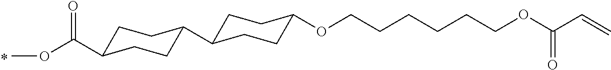 [SMILES: C=CC(=O)OCCCCCCOC1CCC(C2CCC(C(=O)OC)CC2)CC1] |
| 2-14 | 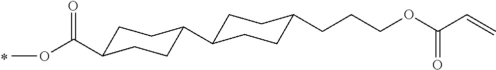 [SMILES: C=CC(=O)OCCCC1CCC(C2CCC(C(=O)OC)CC2)CC1] |

TABLE 3

| | K (side chain structure) |
|---|---|
| 3-1 | 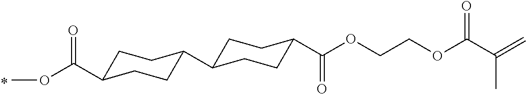 [SMILES: C=C(C)C(=O)OCCOC(=O)C1CCC(C2CCC(C(=O)OC)CC2)CC1] |
| 3-2 | 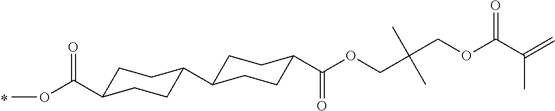 [SMILES: C=C(C)C(=O)OCC(C)(C)COC(=O)C1CCC(C2CCC(C(=O)OC)CC2)CC1] |
| 3-3 | 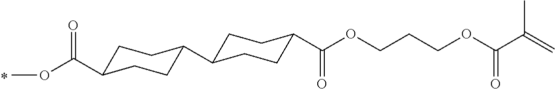 [SMILES: C=C(C)C(=O)OCCCOC(=O)C1CCC(C2CCC(C(=O)OC)CC2)CC1] |
| 3-4 | 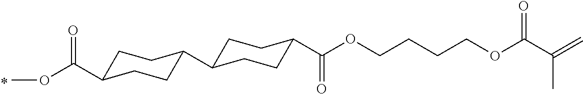 [SMILES: C=C(C)C(=O)OCCCCOC(=O)C1CCC(C2CCC(C(=O)OC)CC2)CC1] |
| 3-5 | 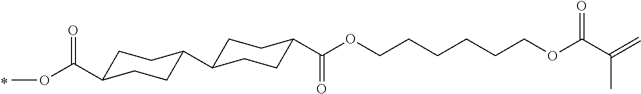 [SMILES: C=C(C)C(=O)OCCCCCCOC(=O)C1CCC(C2CCC(C(=O)OC)CC2)CC1] |
| 3-6 | 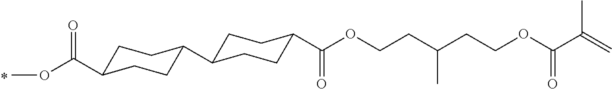 [SMILES: C=C(C)C(=O)OCCC(C)CCOC(=O)C1CCC(C2CCC(C(=O)OC)CC2)CC1] |
| 3-7 | 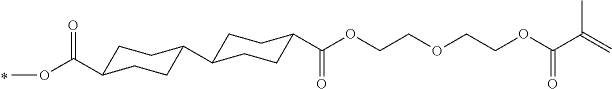 [SMILES: C=C(C)C(=O)OCCOCCOC(=O)C1CCC(C2CCC(C(=O)OC)CC2)CC1] |
| 3-8 | 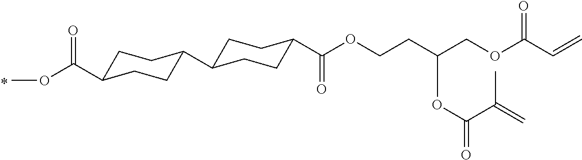 [SMILES: C=CC(=O)OCC(CCOC(=O)C1CCC(C2CCC(C(=O)OC)CC2)CC1)OC(=O)C(=C)C] |
| 3-9 | 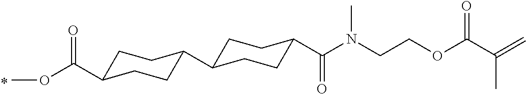 [SMILES: C=C(C)C(=O)OCCN(C)C(=O)C1CCC(C2CCC(C(=O)OC)CC2)CC1] |
| 3-10 | 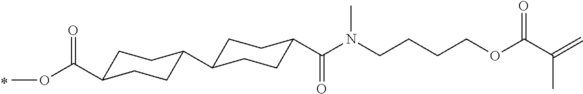 [SMILES: C=C(C)C(=O)OCCCCN(C)C(=O)C1CCC(C2CCC(C(=O)OC)CC2)CC1] |
| 3-11 | 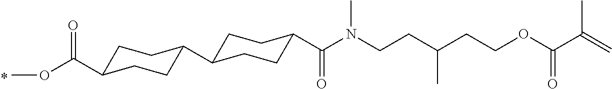 [SMILES: C=C(C)C(=O)OCCC(C)CCN(C)C(=O)C1CCC(C2CCC(C(=O)OC)CC2)CC1] |
| 3-12 | 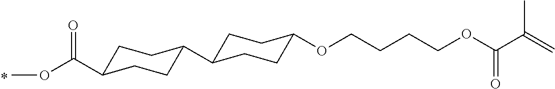 [SMILES: C=C(C)C(=O)OCCCCOC1CCC(C2CCC(C(=O)OC)CC2)CC1] |
| 3-13 | 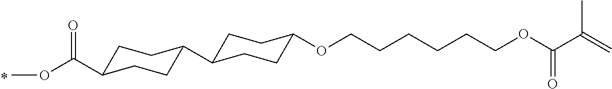 [SMILES: C=C(C)C(=O)OCCCCCCOC1CCC(C2CCC(C(=O)OC)CC2)CC1] |
| 3-14 | 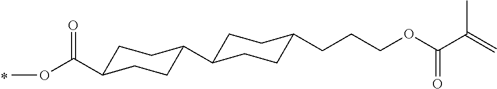 [SMILES: C=C(C)C(=O)OCCCC1CCC(C2CCC(C(=O)OC)CC2)CC1] |

[Freezing Point Depressant]

The freezing point depressant contained in the liquid crystal composition of the embodiment of the present invention is not particularly limited as long as it is the compound satisfying Expression (2-1) or (2-2) in terms of a relationship with the above-mentioned liquid crystal compound among the compounds capable of lowering a freezing point of the above-mentioned liquid crystal compound, that is, a temperature at which the liquid crystal undergoes a phase transition to a crystal.

In the present invention, it is preferable that the freezing point depressant is a non-liquid crystal compound for a reason that the compatibility with the liquid crystal compound is improved.

In the present invention, for a reason that the compatibility with the liquid crystal compound is improved, the freezing point depressant is preferably a compound having a molecular weight of 2,000 or less as the freezing point depressant, and more preferably a compound having a molecular weight of 100 to 1,500.

In the present invention, it is preferable that the freezing point depressant is a compound having a polymerizable group for a reason that the durability of a liquid crystal cured layer thus manufactured is improved.

Examples of the polymerizable group include the same polymerizable groups as those described in P¹ and P² in Formula (II), and among those, suitable examples thereof include the polymerizable group represented by any of Formulae (P-1) to (P-20).

In addition, in a case where the freezing point depressant has a polymerizable group, the number of the polymerizable groups is not particularly limited, but is preferably 1 to 10, and more preferably 2 to 6.

In the present invention, from a reason that the durability of a liquid crystal cured layer thus manufactured is improved, the molar absorption coefficient of the freezing point depressant at a wavelength of 350 to 750 nm is preferably 100 (1/mol·cm) or less, more preferably 0 to 80 (1/mol·cm), still more preferably 0 to 50 (1/mol·cm), particularly preferably 0 to 25 (1/mol·cm), and most preferably 0 to 10 (1/mol·cm).

Specific examples of the freezing point depressant include, among compounds shown below, the compounds that satisfy Expression (2-1) or (2-2) in terms of a relationship to the above-mentioned liquid crystal compound.

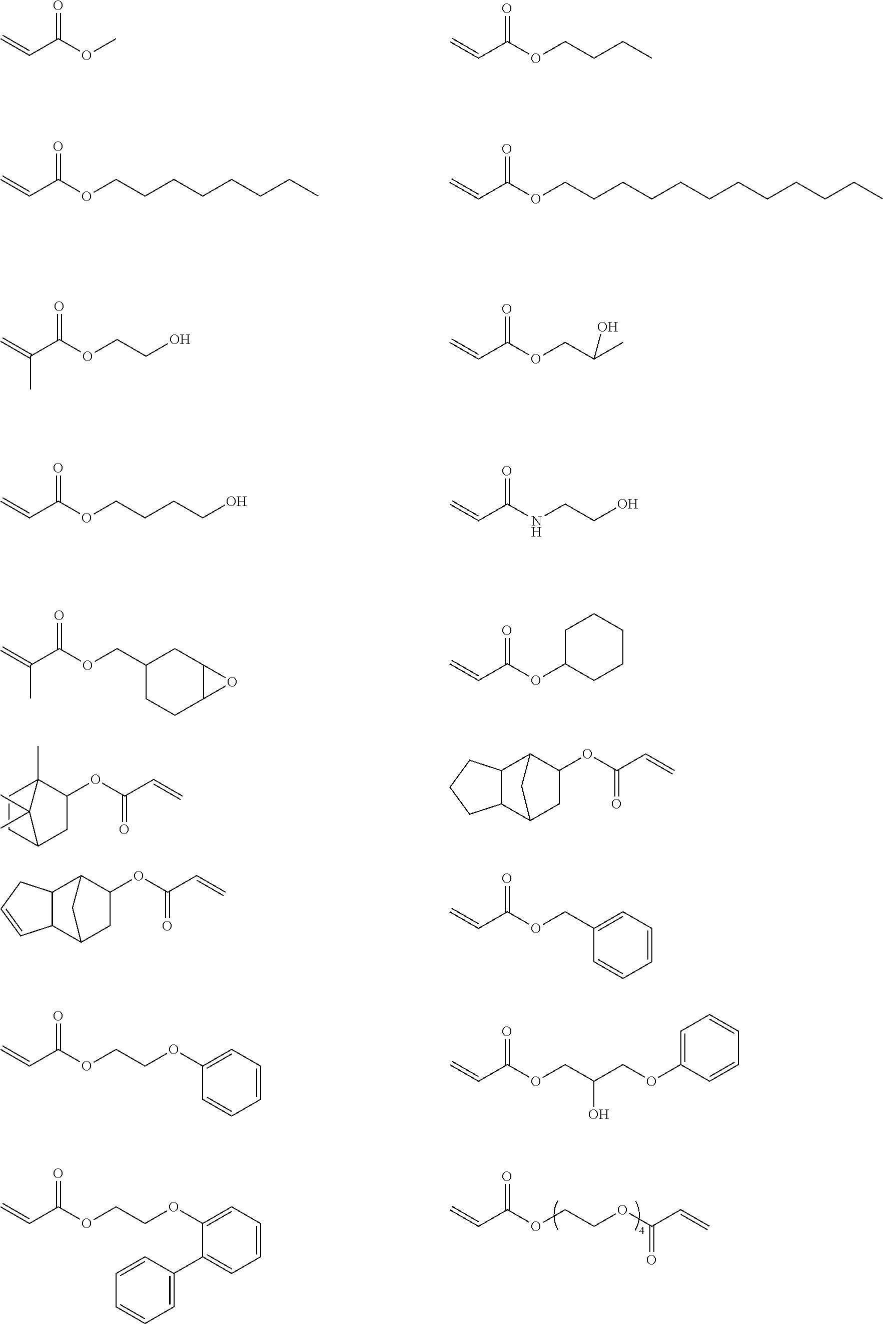

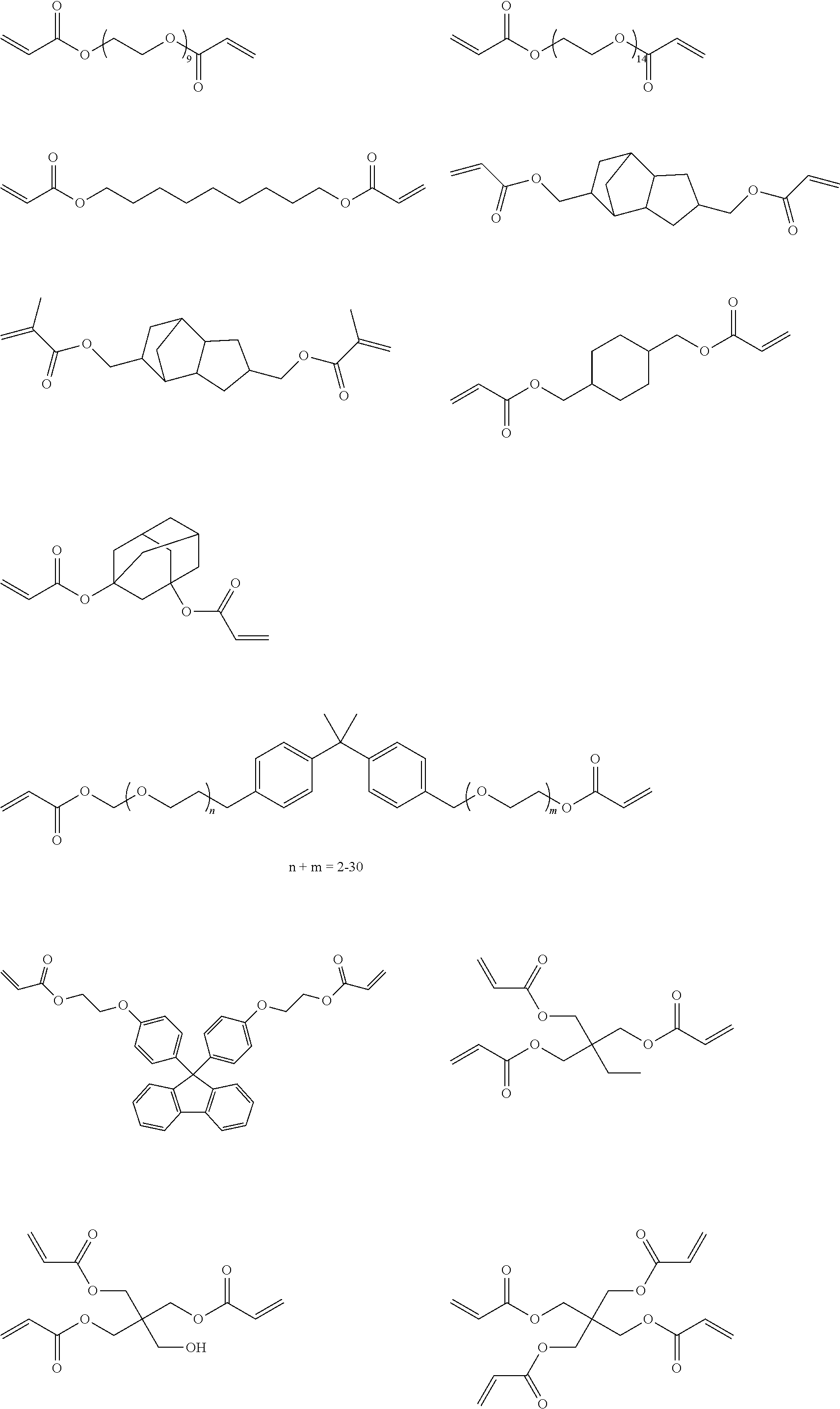

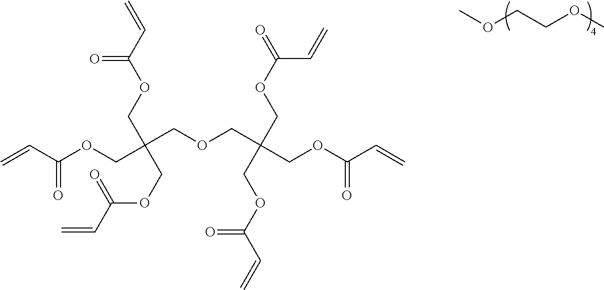

In the present invention, the content of the freezing point depressant is preferably 1 to 30 parts by mass, and more preferably 2 to 15 parts by mass with respect to 100 parts by mass of the above-mentioned liquid crystal compound for a reason that the alignment defects in a liquid crystal cured layer thus formed are further suppressed.

[Polymerization Initiator]

The polymerizable liquid crystal composition of the embodiment of the present invention preferably includes a polymerization initiator.

As the polymerization initiator, a photopolymerization initiator capable of initiating a polymerization reaction upon irradiation with ultraviolet rays is preferable.

Examples of the photopolymerization initiator include α-carbonyl compounds (described in each of the specifications of U.S. Pat. Nos. 2,367,661A and 2,367,670A), acyloin ethers (described in the specification of U.S. Pat. No. 2,448,828A), α-hydrocarbon-substituted aromatic acyloin compounds (described in the specification of U.S. Pat. No. 2,722,512A), multinuclear quinone compounds (described in each of the specifications of U.S. Pat. Nos. 3,046,127A and 2,951,758A), combinations of a triarylimidazole dimer and a p-aminophenyl ketone (described in the specification of U.S. Pat. No. 3,549,367A), acridine and phenazine compounds (described in JP1985-105667A (JP-S60-105667A) and the specification of U.S. Pat. No. 4,239,850A), oxadiazole compounds (described in the specification of U.S. Pat. No. 4,212,970A), and acyl phosphine oxide compounds (described in JP1988-40799B (JP-S63-40799B), JP1993-29234B (JP-H05-29234B), JP1998-95788A (JP-H10-95788A), and JP1998-29997A (JP-H10-29997A)).

As the polymerization initiator, an oxime-type polymerization initiator is also preferable. Specific examples thereof include the initiators described in paragraphs [0049] to [0052] of WO2017/170443A.

[Dichroic Substance]

The liquid crystal composition of the embodiment of the present invention preferably contains a dichroic substance from the viewpoint of using a liquid crystal cured layer which will be described later as a polarizer (light absorption anisotropic film).

The dichroic substance is not particularly limited, examples thereof include a visible light absorbing substance (dichroic coloring agent), a luminescent substance (a fluorescent substance, a phosphorescent substance), an ultraviolet absorbing substance, an infrared absorbing substance, a nonlinear optical substance, a carbon nanotube, and an inorganic substance (for example, a quantum rod), and dichroic substances (dichroic coloring agents) known in the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, paragraphs [0021] to [0030] of WO2018/186503A, paragraphs [0043] to [0063] of WO2019/189345A, paragraphs [0043] to [0085] of WO2019/225468A, paragraphs [0050] to [0074] of WO2020/004106A, and the like.

In the present invention, two or more kinds of dichroic substances may be used in combination, and for example, from the viewpoint of bringing a polarizer (light absorption anisotropic film) as a liquid crystal cured layer which will be described later into black, it is preferable to use at least one dichroic substance having a maximum absorption wavelength in the wavelength range of 370 nm or more and less than 500 nm and at least one dichroic substance having a maximum absorption wavelength in the wavelength range of 500 nm or more and less than 700 nm in combination.

The dichroic substance may have a crosslinkable group.

Specific examples of the crosslinkable group include a (meth)acryloyl group, an epoxy group, an oxetanyl group, and a styryl group, and among these, the (meth)acryloyl group is preferable.

In a case where the liquid crystal composition of the embodiment of the present invention contains a dichroic substance, the content of the dichroic substance is preferably 1 to 400 parts by mass, more preferably 2 to 100 parts by mass, and still more preferably 5 to 30 parts by mass with respect to 100 parts by mass of the liquid crystal compound.

In addition, the content of the dichroic substance is preferably 1% to 50% by mass, and more preferably 2% to 40% by mass in the solid content of the liquid crystal composition.

[Solvent]

It is preferable that the liquid crystal composition of the embodiment of the present invention includes a solvent from the viewpoint of workability in a case where a liquid crystal cured layer is formed.

Examples of the solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide). The solvents may be used singly or in combination of two or more kinds thereof

[Leveling Agent]

It is preferable that the liquid crystal composition of the embodiment of the present invention includes a leveling agent from the viewpoint that a surface of a liquid crystal cured layer is maintained smooth and the alignment is easily controlled.

Such a leveling agent is preferably a fluorine-based leveling agent or a silicon-based leveling agent for a reason that it has a high leveling effect on the addition amount, and the leveling agent is more preferably a fluorine-based leveling agent from the viewpoint that it is less likely to cause bleeding (bloom or bleed).

Examples of the leveling agent include the compounds described in paragraphs [0079] to [0102] of JP2007-069471A, the compound represented by General Formula (I) described in JP2013-047204A (in particular, the compounds described in paragraphs [0020] to [0032]), the compound represented by General Formula (I) described in JP2012-211306A (in particular, the compounds described in paragraphs [0022] to [0029]), the liquid crystal alignment accelerator represented by General Formula (I) described in JP2002-129162A (in particular, the compounds described in paragraphs [0076] to [0078] and [0082] to [0084]), and the compounds represented by General Formulae (I), (II), and (III) described in JP2005-099248A (in particular, the compounds described in paragraphs [0092] to [0096]). Furthermore, the leveling agent may also function as an alignment control agent which will be described later.

[Alignment Control Agent]

The liquid crystal composition of the embodiment of the present invention may include an alignment control agent as necessary.

With the alignment control agent, various alignment states such as homeotropic alignment (vertical alignment), tilt alignment, hybrid alignment, and cholesteric alignment can be formed, in addition to the homogeneous alignment, and specific alignment states can be controlled and realized more uniformly and more accurately.

As an alignment control agent which accelerates the homogeneous alignment, for example, a low-molecular-weight alignment control agent and a high-molecular-weight alignment control agent can be used.

With regard to the low-molecular-weight alignment control agent, reference can be made to the description in, for example, paragraphs [0009] to [0083] of JP2002-20363A, paragraphs [0111] to [0120] of JP2006-106662A, and paragraphs [0021] to [0029] of JP2012-211306A, the contents of which are hereby incorporated by reference.

In addition, with regard to the high-molecular-weight alignment control agent, reference can be made to the description in, for example, paragraphs [0021] to [0057] of JP2004-198511A and paragraphs [0121] to [0167] of JP2006-106662A, the contents of which are hereby incorporated by reference.

Moreover, examples of an alignment control agent which forms or accelerates a homeotropic alignment include a boronic acid compound and an onium salt compound. With regard to the alignment control agent, reference can be made to the description in the compounds described in paragraphs [0023] to [0032] of JP2008-225281A, paragraphs [0052] to [0058] of JP2012-208397A, paragraphs [0024] to [0055] of JP2008-026730A, and paragraphs [0043] to [0055] of JP2016-193869A, the contents of which are hereby incorporated by reference.

On the other hand, the cholesteric alignment can be realized by adding a chiral agent to the liquid crystal composition of the embodiment of the present invention, and it is possible to control the direction of revolution of the cholesteric alignment by its chiral direction.

Incidentally, the pitch of the cholesteric alignment in accordance with the alignment restricting force of the chiral agent may be controlled.

In a case where the liquid crystal composition of the embodiment of the present invention includes an alignment control agent, a content thereof is preferably 0.01% to 10% by mass, and more preferably 0.05% to 5% by mass with respect to the mass of the total solid content of the composition. In a case where the content is within the range, it is possible to obtain a uniform and highly transparent cured product, in which precipitation, phase separation, alignment defects, and the like are suppressed while a desired alignment state is achieved.

[Other Components]

The liquid crystal composition of the embodiment of the present invention may include components other than the above-mentioned components. Examples of such other components include a liquid crystal compound (for example, the liquid crystal compound not satisfying Expression (1)) other than the above-mentioned liquid crystal compound, a surfactant, a tilt angle control agent, an alignment aid, a plasticizer, and a crosslinking agent.

[Suppressing Method]

The present invention provides, in addition to the above-mentioned liquid crystal composition, a method for suppressing crystallization while suppressing a decrease in phase transition temperature of a liquid crystal compound exhibiting smectic properties from a smectic phase to a nematic phase, by mixing the liquid crystal compound with a freezing point depressant (hereinafter also simply referred to as “the suppressing method of an embodiment of the present invention”).

That is, the suppressing method according to the embodiment of the present invention is a method of mixing the above-mentioned freezing point depressant with the above-mentioned liquid crystal compound to satisfy Expression (1) and Expression (2-1) or (2-2).

[Liquid Crystal Cured Layer]

The liquid crystal cured layer of an embodiment of the present invention is a liquid crystal cured layer obtained by immobilizing the alignment state of the above-mentioned liquid crystal composition of the embodiment of the present invention.

Examples of a method for forming the liquid crystal cured layer include a method in which the above-mentioned liquid crystal composition of the embodiment of the present invention is used to cause a desired alignment state, which is then immobilized by polymerization.

Here, the polymerization conditions are not particularly limited, but in the polymerization by irradiation with light, ultraviolet rays are preferably used. The irradiation dose is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm². In addition, the polymerization may be carried out under a heating condition in order to accelerate the polymerization reaction.

In addition, the liquid crystal cured layer can be formed on any of supports or alignment films in the optical film which will be described later or a polarizer in the polarizing plate which will be described later.

The liquid crystal cured layer of the embodiment of the present invention preferably shows a diffraction peak derived from a periodic structure in X-ray diffraction measurement.

Here, suitable examples of an aspect exhibiting the above-mentioned diffraction peak include an aspect in which molecules adjacent in the direction vertical to the alignment axis form a layer and this layer is laminated in the direction parallel to the alignment axis, that is, an aspect exhibiting a smectic phase. Furthermore, from the viewpoint that the smectic phase is easily expressed, it is preferable that the above-mentioned liquid crystal compound is a compound exhibiting a smectic phase in any of a case where the temperature is elevated and a case where the temperature is lowered.

In addition, whether or not the above-mentioned diffraction peak is exhibited can also be confirmed by observing a texture characteristic of a liquid crystal phase having a periodic structure with a polarization microscope.

The alignment state of the liquid crystal compound in the liquid crystal cured layer of the embodiment of the present invention may be any of horizontal alignment, vertical alignment, tilt alignment, and twist alignment, and it is preferable that the liquid crystal compound is immobilized in a state of being horizontally aligned with respect to the main surface of the liquid crystal cured layer.

In addition, in the present specification, the “horizontal alignment” means that the main surface of a liquid crystal cured layer (or in a case where the liquid crystal cured layer is formed on a member such as a support and an alignment film, a surface of the member) and the major axis direction of the liquid crystal compound are parallel to each other. Incidentally, it is not required for the both to be strictly parallel, and in the present specification, the expression means that the both are aligned at an angle formed by the major axis direction of the liquid crystal compound and the main surface of the liquid crystal cured layer of less than 10°.

In the liquid crystal cured layer, the angle formed by the major axis direction of the liquid crystal compound and the main surface of the liquid crystal cured layer is preferably 0 to 5°, more preferably 0 to 3°, and still more preferably 0 to 2°.

The liquid crystal cured layer of the embodiment of the present invention is preferably an optically anisotropic layer, more preferably a positive A plate or a positive C plate, and still more preferably the positive A plate.

Here, the positive A plate (A-plate which is positive) and the positive C plate (C plate which is positive) are defined as follows.

In a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz, the positive A plate satisfies the relationship of Expression (A1) and the positive C plate satisfies the relationship of Expression (C1). In addition, the positive A plate has an Rth showing a positive value and the positive C plate has an Rth showing a negative value.

nx>ny≈nz Expression (A1)

nz>nx≈ny Expression (C1)

Furthermore, the symbol, “≈”, encompasses not only a case where the both sides are completely the same as each other but also a case where the both are substantially the same as each other.

In the expression, “substantially the same”, with regard to the positive A plate, for example, a case where (ny−nz)×d (in which d is the thickness of a film) is −10 to 10 nm, and preferably −5 to 5 nm is also included in “ny≈nz”, and a case where (nx−nz) x d is −10 to 10 nm, and preferably −5 to 5 nm is also included in “nx≈nz”. In addition, with regard to the positive C plate, for example, a case where (nx−ny)×d (in which d is the thickness of a film) is 0 to 10 nm, and preferably 0 to 5 nm is also included in “nx≈ny”.

In a case where the liquid crystal cured layer of the embodiment of the present invention is a positive A plate, the Re(550) is preferably 100 to 180 nm, more preferably 120 to 160 nm, still more preferably 130 to 150 nm, and particularly preferably 130 to 140 nm, from the viewpoint that the liquid crystal cured layer functions as a λ/4 plate.

Here, the “λ/4 plate” is a plate having a λ/4 function, specifically, a plate having a function of converting a linearly polarized light at a certain specific wavelength into a circularly polarized light (or converting a circularly polarized light to a linearly polarized light).

The liquid crystal cured layer of the embodiment of the present invention is preferably a polarizer (light absorption anisotropic film).

[Optical Film]

The optical film of an embodiment of the present invention is an optical film having the liquid crystal cured layer of the embodiment of the present invention.

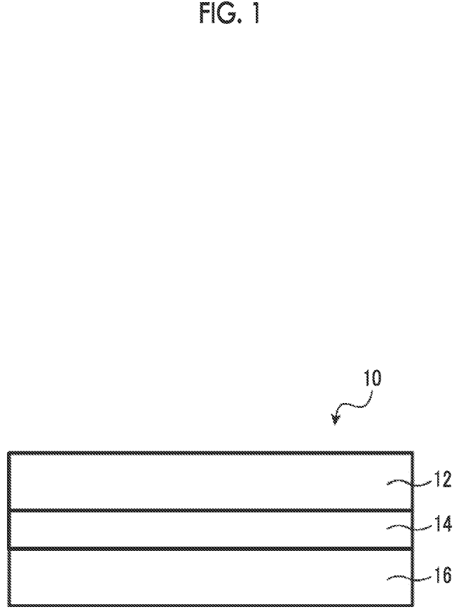

The structure of the optical film will be described with reference to FIG. 1. FIG. 1 is a schematic cross-sectional view showing an example of the optical film.

Furthermore, FIG. 1 is a schematic view, and the thicknesses relationship, the positional relationship, and the like among the respective layers are not necessarily consistent with actual ones, and either of the support shown in FIG. 1 and an alignment film are optional constitutional members.

An optical film 10 shown in FIG. 1 has a support 16, an alignment film 14, and a liquid crystal cured layer 12 as the cured product of the liquid crystal composition of the embodiment of the present invention in this order.

In addition, the liquid crystal cured layer 12 may be a laminate of two or more different liquid crystal cured layers. For example, in a case where the polarizing plate of the embodiment of the present invention which will be described later is used as a circularly polarizing plate or in a case where the optical film of the embodiment of the present invention is used as an optical compensation film for an IPS mode or an FFS mode liquid crystal display device, the liquid crystal cured layer is preferably a laminate of a positive A plate and a positive C plate.

In addition, the liquid crystal cured layer may be peeled from the support, and the liquid crystal cured layer may be used alone as an optical film.

Hereinafter, various members used for the optical film will be described in detail.

[Liquid Crystal Cured Layer]

The liquid crystal cured layer contained in the optical film of the embodiment of the present invention is the above-mentioned liquid crystal cured layer of the embodiment of the present invention.

In the optical film, a thickness of the liquid crystal cured layer is not particularly limited, but is preferably 0.1 to 10 and more preferably 0.5 to 5

[Support]

The optical film may have a support as a base material for forming a liquid crystal cured layer as described above.

Such a support is preferably transparent. Specifically, the light transmittance is preferably 80% or more.

Examples of such a support include a glass substrate and a polymer film. Examples of the material for the polymer film include cellulose-based polymers; acrylic polymers having an acrylic ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

In addition, an aspect in which a polarizer which will be described later may also function as such a support is also available.

A thickness of the support is not particularly limited, but is preferably 5 to 60 and more preferably 5 to 40

[Alignment Film]

In the optical film, the liquid crystal cured layer is preferably formed on a surface of an alignment films. In a case where the optical film has any of the above-mentioned supports, it is preferable that the alignment film may be sandwiched between the support and the liquid crystal cured layer. In addition, an aspect in which the above-mentioned support may also function as an alignment film is also available.

The alignment film may be any film as long as it has a function of horizontally aligning the polymerizable liquid crystal compound included in the composition.

The alignment film generally has a polymer as a main component. Polymer materials for the alignment film are described in many documents, and many commercially available products thereof can be used.

As the polymer material for the alignment film, a polyvinyl alcohol, a polyimide, or a derivative thereof is preferable, and a modified or unmodified polyvinyl alcohol is more preferable.

Examples of the alignment film which may be contained in the optical film include the alignment films described for Line 24 on Page 43 to Line 8 on Page 49 of WO01/88574A; the alignment films consisting of modified polyvinyl alcohols described in paragraphs [0071] to [0095] of JP3907735B; and the liquid crystal alignment film formed by a liquid crystal alignment agent described in JP2012-155308A.

Since an object does not come into contact with a surface of the alignment film upon formation of the alignment film and the deterioration of a surface condition can be prevented, it is preferable to use a photo-alignment film as the alignment film.

The photo-alignment film is not particularly limited, but an alignment film formed by the polymer material such as a polyamide compound and a polyimide compound described in paragraphs [0024] to [0043] of WO2005/096041A; a liquid crystal alignment film formed by the liquid crystal alignment agent having a photo-aligned group described in JP2012-155308A; LPP-JP265CP, trade name, manufactured by Rolic Technologies Ltd.; or the like can be used.

A thickness of the alignment film is not particularly limited, but from the viewpoint of forming a liquid crystal cured layer having a uniform film thickness by relaxing the surface roughness that can be present on the support, the thickness is preferably 0.01 to 10 more preferably 0.01 to 1 and still more preferably 0.01 to 0.5

[Ultraviolet Absorbing Agent]

The optical film preferably includes an ultraviolet (UV) absorbing agent, taking an effect of external light (particularly ultraviolet rays) into consideration.

The ultraviolet absorbing agent may be included in the liquid crystal cured layer or may also be included in a member other than the liquid crystal cured layer, constituting the optical film. Suitable examples of the member other than the liquid crystal cured layer include a support.

As the ultraviolet absorbing agent, any of ultraviolet absorbing agents known in the related art, which can express ultraviolet absorptivity, can be used. Among such the ultraviolet absorbing agents, a benzotriazole-based or hydroxyphenyltriazine-based ultraviolet absorbing agent is preferable from the viewpoint that it has high ultraviolet absorptivity and ultraviolet absorbing ability (ultraviolet-shielding ability) used for an image display device is obtained.

In addition, in order to broaden ultraviolet absorbing ranges, two or more kinds of ultraviolet absorbing agents having different maximum absorption wavelengths are also preferably used.

Examples of the ultraviolet absorbing agent include the compounds described in paragraphs [0258] and [0259] of JP2012-18395A and the compounds described in paragraphs [0055] to [0105] of JP2007-72163A.

In addition, as a commercially available product thereof, for example, Tinuvin 400, Tinuvin 405, Tinuvin 460, Tinuvin 477, Tinuvin 479, and Tinuvin 1577 (all manufactured by BASF), or the like can be used.

[Polarizing Plate]

The polarizing plate according to a first aspect of the present invention has a liquid crystal cured layer (optically anisotropic layer) obtained by immobilizing an alignment state of a liquid crystal composition which does not contain any dichroic substance among the above-mentioned liquid crystal compositions of the embodiment of the present invention, and a polarizer.

The polarizing plate according to a second aspect of the present invention has a phase difference film and a liquid crystal cured layer (light absorption anisotropic layer) obtained by immobilizing an alignment state of a liquid crystal composition which contains any dichroic substance among the above-mentioned liquid crystal compositions of the present invention.

The polarizing plate according to a third aspect of the present invention has a liquid crystal cured layer (optically anisotropic layer) obtained by immobilizing an alignment state of the liquid crystal composition which does not contain any dichroic substance among the above-mentioned liquid crystal compositions of the embodiment of the present invention, and a liquid crystal cured layer (light absorption anisotropic layer) obtained by immobilizing an alignment state of the liquid crystal composition which contains any dichroic substance among the above-mentioned liquid crystal compositions of the embodiment of the present invention.

In a case where the above-mentioned liquid crystal cured layer is a λ/4 plate (positive A plate), the polarizing plate according to the first aspect can be used as a circularly polarizing plate.

In a case where the polarizing plate is used as a circularly polarizing plate, the above-mentioned liquid crystal cured layer is used as a λ/4 plate (positive A plate), and an angle between the slow axis of the λ/4 plate and the absorption axis of a polarizer which will be described later is preferably 30° to 60°, more preferably 40° to 50°, still more preferably 42° to 48°, and particularly preferably 45°.

Here, the “slow axis” of the λ/4 plate means a direction in which the refractive index in the plane of the λ/4 plate is maximum, and the “absorption axis” of the polarizer means a direction in which the absorbance is highest.

In addition, the polarizing plate can also be used as an optical compensation film for an IPS mode or FFS mode liquid crystal display device.

In a case where the polarizing plate is used as an optical compensation film for an IPS mode or FFS mode liquid crystal display device, it is preferable that the above-mentioned liquid crystal cured layer is used as at least one plate of a laminate of a positive A plate or a positive C plate, an angle formed by the slow axis of the positive A plate layer and the absorption axis of a polarizer which will be described later are orthogonal or parallel, and specifically, it is more preferable that an angle formed by the slow axis of the positive A plate layer and the absorption axis of the polarizer which will be described later is 0° to 5° or 85° to 95°.

In a case where the polarizing plate according to the first aspect of the present invention is used in a liquid crystal display device which will be described later, it is preferable that an angle formed by the slow axis of the liquid crystal cured layer and the absorption axis of a polarizer which will be described later is parallel or orthogonal to each other.

In addition, in the present specification, a term “parallel” does not require that the both are strictly parallel, but means that an angle between one and the other is less than 10°. In addition, in the present specification, a term “orthogonal” does not require that the both are strictly orthogonal, but means that the angle between one and the other is more than 80° and less than 100°.

[Polarizer]

The polarizer having the polarizing plate according to the first aspect of the present invention is not particularly limited as long as it is a member having a function of converting light into specific linearly polarized light, and an absorptive type polarizer and a reflective type polarizer, which are known in the related art, can be used.

An iodine-based polarizer, a dye-based polarizer using a dichroic dye, a polyene-based polarizer, or the like is used as the absorptive type polarizer. The iodine-based polarizer and the dye-based polarizer are classified into a coating type polarizer and a stretching type polarizer, any of which can be applied, but a polarizer which is manufactured by allowing polyvinyl alcohol to adsorb iodine or a dichroic dye and performing stretching is preferable.

In addition, examples of a method of obtaining a polarizer by carrying out stretching and dying in a state of a laminated film in which a polyvinyl alcohol layer is formed on a base material include the methods disclosed in JP5048120B, JP5143918B, JP4691205B, JP4751481B, and JP4751486B, and known technologies relating to these polarizers can also be preferably used.

Examples of the coating type polarizer include those in WO2018/124198A, WO2018/186503A, WO2019/132020A, WO2019/132018A, WO2019/189345A, JP2019-197168A, JP2019-194685A, and JP2019-139222A, and known techniques relating to these polarizers can also be preferably used.

A polarizer in which thin films having different birefringence are laminated, a wire grid-type polarizer, a polarizer having a combination of a cholesteric liquid crystal having a selective reflection range, a ¼ wavelength plate, and the like is used as the reflective type polarizer.

Among those, from the viewpoint that it has more excellent adhesiveness, a polarizer including a polyvinyl alcohol-based resin (a polymer including —CH₂—CHOH— as a repeating unit, and in particular, at least one selected from the group consisting of polyvinyl alcohol and an ethylene-vinyl alcohol copolymer) is preferable.

In addition, from the viewpoint of imparting crack resistance, the polarizer may have a depolarization unit formed along the opposite end edges. Examples of the depolarization unit include JP2014-240970A.

In addition, the polarizer may have non-polarizing parts arranged at predetermined intervals in the longitudinal direction and/or the width direction. The non-polarizing part is a decolorized part which is partially decolorized. The arrangement pattern of the non-polarizing parts can be appropriately set according to a purpose. For example, the non-polarizing parts are arranged at a position corresponding to a camera unit of an image display device in a case where a polarizer is cut (cut, punched, or the like) to a predetermined size in order to be attached to the image display device in a predetermined size. Examples of the arrangement pattern of the non-polarizing parts include those in JP2016-27392A.

A thickness of the polarizer is not particularly limited, but is preferably 3 to 60 μm, more preferably 3 to 30 μm, and still more preferably 3 to 10 μm.

[Pressure Sensitive Adhesive Layer]

In the polarizing plate, a pressure sensitive adhesive layer may be arranged between the liquid crystal cured layer in the optical film and the polarizer.

Examples of a material forming the pressure sensitive adhesive layer used for lamination of the cured product and the polarizer include a member formed of a substance in which a ratio (tan δ=G″/G′) between a storage elastic modulus G′ and a loss elastic modulus G″, each measured with a dynamic viscoelastometer, is 0.001 to 1.5, in which a so-called pressure sensitive adhesive and a readily creepable substance is included. Examples of the pressure sensitive adhesive include a polyvinyl alcohol-based pressure sensitive adhesive, but the pressure sensitive adhesive is not limited thereto.

[Adhesive Layer]

In the polarizing plate, an adhesive layer may be arranged between the liquid crystal cured layer in the optical film and the polarizer.

As the adhesive layer used for laminating a cured product and a polarizer, a curable adhesive composition that is cured by irradiation with active energy rays or heating is preferable.

Examples of the curable adhesive composition include a curable adhesive composition containing a cationically polymerizable compound and a curable adhesive composition containing a radically polymerizable compound.

A thickness of the adhesive layer is preferably 0.01 to 20 um, more preferably 0.01 to 10 um, and still more preferably 0.05 to 5 μm. In a case where the thickness of the adhesive layer is within this range, floating or peeling does not occur between the protective layer or liquid crystal cured layer and the polarizer, which are laminated, and a practically acceptable adhesive force can be obtained. In addition, the thickness of the adhesive layer is preferably 0.4 um or more from the viewpoint that the generation of air bubbles can be suppressed.

Moreover, from the viewpoint of durability, a bulk water absorption rate of the adhesive layer may be adjusted to 10% by mass or less, and is preferably 2% by mass or less. The bulk water absorption rate is measured according to the water absorption rate testing method described in JIS K 7209.

With regard to the adhesive layer, reference can be made to the description in paragraphs [0062] to [0080] of JP2016-35579A, the contents of which are incorporated herein by reference.

[Easy Adhesion Layer]

In the polarizing plate, an easy adhesion layer may be arranged between the liquid crystal cured layer in the optical film and the polarizer. A storage elastic modulus of the easy adhesion layer at 85° C. is preferably 1.0×10⁶ Pa to 1.0×10⁷ Pa from the viewpoints that the adhesiveness between the liquid crystal cured layer and the polarizer is excellent and the generation of cracks in the polarizer is suppressed. Examples of the constituent material of the easy adhesion layer include a polyolefin-based component and a polyvinyl alcohol-based component. A thickness of the easy adhesion layer is preferably 500 nm to 1 μm.

With regard to the easy adhesion layer, reference can be made to the description in paragraphs [0048] to [0053] of JP2018-36345A, the contents of which are incorporated herein by reference.

[Image Display Device]

An image display device of an embodiment of the present invention is an image display device having the optical film of the embodiment of the present invention or the polarizing plate of the embodiment of the present invention.

A display element used in the image display device is not particularly limited, and examples thereof include a liquid crystal cell, an organic electroluminescent (hereinafter simply referred to as “electroluminescence (EL)”) display panel, and a plasma display panel. Among those, the liquid crystal cell and the organic EL display panel are preferable, and the liquid crystal cell is more preferable.

That is, as the image display device, a liquid crystal display device using a liquid crystal cell as a display element or an organic EL display device using an organic EL display panel as a display element is preferable, and the liquid crystal display device is more preferable.

[Liquid Crystal Display Device]

A liquid crystal display device which is an example of the image display device is a liquid crystal display device having the above-mentioned polarizing plate and a liquid crystal cell.

Furthermore, it is preferable that the above-mentioned polarizing plate is used as the polarizing plate of the front side, and it is more preferable that the above-mentioned polarizing plate is used as the polarizing plates on the front and rear sides, among the polarizing plates provided on the both sides of the liquid crystal cell.

Hereinafter, the liquid crystal cell constituting the liquid crystal display device will be described in detail.

<Liquid Crystal Cell>

The liquid crystal cell used in the liquid crystal display device is a vertical alignment (VA) mode, an optically compensated bend (OCB) mode, an in-plane-switching (IPS) mode, a fringe-field-switching (FFS) mode, or a twisted nematic (TN) mode is preferred, but is not limited to these.

In a TN-mode liquid crystal cell, rod-like liquid crystal molecules are substantially horizontally aligned and are twist-aligned at 60° to 120° during no voltage application thereto. A TN-mode liquid crystal cell is most often used in a color TFT liquid crystal display device and described in numerous documents.

In a VA-mode liquid crystal cell, rod-like liquid crystal molecules are substantially vertically aligned during no voltage application thereto. Examples of the VA-mode liquid crystal cell include (1) a VA-mode liquid crystal cell in the narrow sense of the word, in which rod-like liquid crystal molecules are substantially vertically aligned during no voltage application thereto, but are substantially horizontally aligned during voltage application thereto (described in JP1990-176625A (JP-H02-176625A)), (2) an MVA-mode liquid crystal cell in which the VA-mode is multi-domained for viewing angle enlargement (described in SID97, Digest of tech. Papers (preprint), 28 (1997) 845), (3) a liquid crystal cell in a mode (n-ASM mode) in which rod-like liquid crystal molecules are substantially vertically aligned during no voltage application thereto and are multi-domain-aligned during voltage application thereto (described in Seminar of Liquid Crystals of Japan, Papers (preprint), 58-59 (1998)), and (4) a survival-mode liquid crystal cell (announced in LCD International 98). In addition, the liquid crystal cell in the VA mode may be any of a patterned vertical alignment (PVA) type, an optical alignment type, and a polymer-sustained alignment (PSA) type. Details of these modes are specifically described in JP2006-215326A and JP2008-538819A.

In an IPS-mode liquid crystal cell, rod-like liquid crystal molecules are aligned substantially parallel with respect to a substrate, and application of an electric field parallel to the substrate surface causes the liquid crystal molecules to respond planarly. The IPS-mode displays black in a state where no electric field is applied and a pair of upper and lower polarizing plates have absorption axes which are orthogonal to each other. A method of improving the viewing angle by reducing light leakage during black display in an oblique direction using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

[Organic EL Display Device]

Examples of the organic EL display device which is an example of the image display device include an aspect which includes, from the visible side, a polarizer, a λ/4 plate (a positive A plate) consisting of the above-mentioned liquid crystal cured layer, and an organic EL display panel in this order.

In addition, the organic EL display panel is a display panel composed of an organic EL device in which an organic light emitting layer (organic electroluminescent layer) is sandwiched between electrodes (between a cathode and an anode). The configuration of the organic EL display panel is not particularly limited but a known configuration is adopted.

### Examples

Hereinbelow, the present invention will be described in more detail with reference to Examples. The materials, the amounts of materials used, the proportions, the treatment details, the treatment procedure, and the like shown in Examples below can be appropriately modified as long as the modifications do not depart from the spirit of the present invention. Therefore, the scope of the present invention should not be construed as being limited to Examples shown below.

### Example 1

[Manufacture of Protective Film 1]

<Preparation of Core Layer Cellulose Acylate Dope 1>

The following composition was put into a mixing tank and stirred to dissolve the respective components, thereby preparing a core layer cellulose acylate dope 1.

Core layer cellulose acylate dope 1

| | |
|---|---|
| Cellulose acetate having a degree of acetyl | 100 parts by mass |
| substitution of 2.88 | |
| The following polyester | 12 parts by mass |
| The following durability improver | 4 parts by mass |
| Methylene chloride (the first solvent) | 430 parts by mass |
| Methanol (the second solvent) | 64 parts by mass |

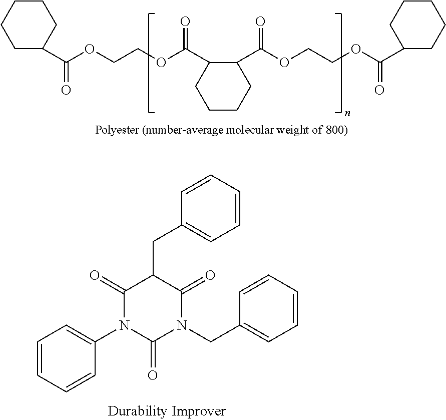

<Preparation of Outer Layer Cellulose Acylate Dope 1>

10 parts by mass of the following matting agent dispersion liquid 1 was added to 90 parts by mass of the core layer cellulose acylate dope 1 to prepare an outer layer cellulose acylate dope 1.

Matting agent dispersion liquid 1

| | |
|---|---|
| Silica particles with an average particle size | 2 parts by mass |
| of 20 nm (AEROSIL R972, manufactured | |
| by Nippon Aerosil Co., Ltd.) | |
| Methylene chloride (the first solvent) | 76 parts by mass |
| Methanol (the second solvent) | 11 parts by mass |
| Core layer cellulose acylate dope 1 | 1 part by mass |

<Manufacture of Protective Film 1>

The core layer cellulose acylate dope 1 and the outer layer cellulose acylate dope 1 were filtered, using a filter paper with an average pore diameter of 34 μm and a sintered metal filter with an average pore diameter of 10 Then, the core layer cellulose acylate dope 1 and the outer layer cellulose acylate dopes 1 on both sides thereof were cast simultaneously on a drum at 20° C. from a casting port in three layers, using a band casting machine.

Subsequently, the film was peeled from the drum in a state where a solvent content of the film on the drum was approximately 20% by mass. Both ends of the obtained film in the width direction were fixed with tenter clips, and the film was dried while being stretched 1.1 times in the width direction in a state where the solvent content of the film was 3% to 15% by mass.

Then, the obtained film was transported between rolls of a heat treatment device and further dried to manufacture a cellulose acylate film 1 with a film thickness of 40 which was used as a protective film 1. The results of measuring a phase difference of the protective film 1 were as follows: Re=1 nm and Rth=−5 nm.

[Manufacture of Optically Anisotropic Layer 1]

<Preparation of Composition 1 for Photo-Alignment Film>

8.4 parts by mass of the following copolymer C1 and 0.3 parts by mass of the following thermal acid generator D1 were added to a mixed liquid including 80 parts by mass and 20 parts by mass of butyl acetate and methyl ethyl ketone, respectively, to prepare a composition 1 for a photo-alignment film.

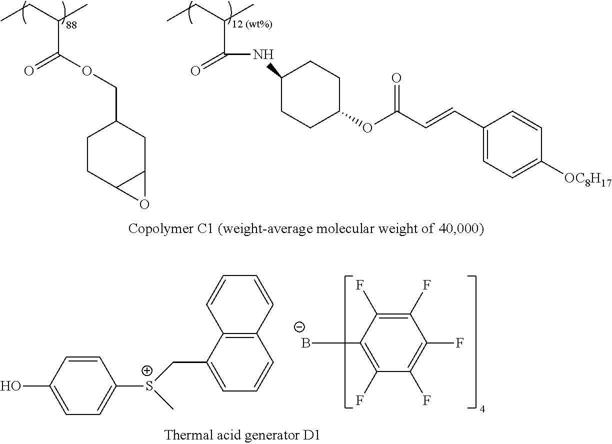

<Preparation of Liquid Crystal Composition 1>

A liquid crystal composition 1 for forming an optically anisotropic layer having the following composition was prepared.

Liquid crystal composition 1

| | |
|---|---|
| The following liquid crystal compound R1 | 80.00 parts by mass |
| The following liquid crystal compound R2 | 20.00 parts by mass |
| The following freezing point depressant A1 | 10.00 parts by mass |
| The following polymerization initiator S1 | 0.50 parts by mass |
| The following leveling agent P1 | 0.23 parts by mass |
| Cyclopentanone | 284.73 parts by mass |

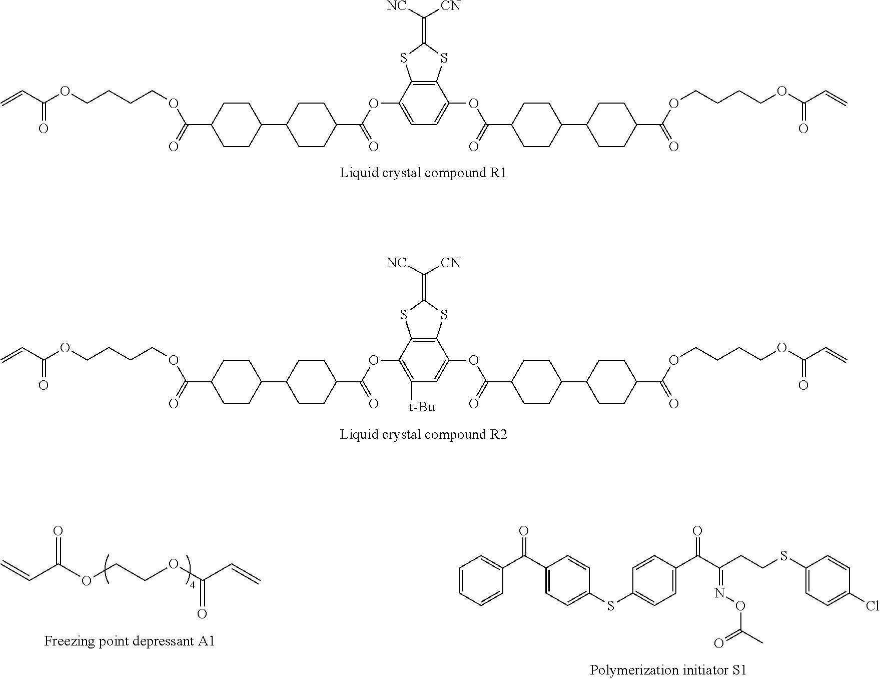

Leveling agent P1 (in the following formula: 32.5 and 67.5 indicate contents (% by mass) of the respective repeating units with respect to all repeating units in the leveling agent P1)

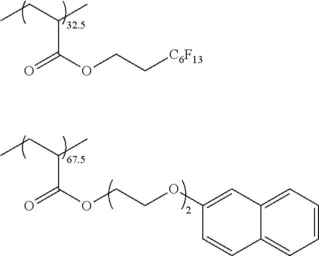

<Manufacture of Optically Anisotropic Layer 1>

The composition 1 for the photo-alignment film prepared in advance was continuously applied onto a surface on one side of the manufactured cellulose acylate film 1 with a bar coater. After the application, the solvent was removed by drying in a heating zone at 120° C. for 1 minute to form a 0.3 μm-thick photoisomerization composition layer. Subsequently, a photo-alignment film was formed through irradiation with polarized ultraviolet rays (10 mJ/cm², using an ultra-high-pressure mercury lamp) while winding a mirror-treated backup roll.

Next, the liquid crystal composition 1 prepared above was applied onto the photo-alignment film formed in a long shape with a bar coater to form a composition layer. In addition, the temperature of the coating chamber was set to 23° C. The formed composition layer was heated in a heating zone to a temperature exhibiting a nematic phase, and then cooled to stabilize the alignment at a temperature exhibiting a smectic phase. Thereafter, while maintaining the temperature, the alignment was immobilized by irradiation with ultraviolet rays (500 mJ/cm², using an ultra-high-pressure mercury lamp) in a nitrogen atmosphere (an oxygen concentration of 100 ppm) to form an optically anisotropic layer 1 with a thickness of 2.2 μm.

In a case where the obtained optically anisotropic layer 1 was peeled from the protective film 1 and a phase difference of the optically anisotropic layer 1 was measured, the in-plane retardation Re1 (550) was 117 nm, Re1 (450)/Re1 (550) was 0.68, and the optically anisotropic layer 1 was confirmed to be a positive A plate.

[Evaluation]

<Phase Transition Temperature>

The phase transition temperature of the liquid crystal composition 1 was confirmed by observing the texture with a polarization microscope.

The liquid crystal composition 1 had a change from a crystal to a liquid crystal phase having a texture peculiar to the smectic phase at around 84° C. in a temperature decrease in a case of a temperature increase to 200° C. It was confirmed that in a case where the temperature was further increased, the phase changed to a nematic phase at around 136° C., and the nematic phase was maintained up to around 200° C.

Further, the phase transition temperature of the liquid crystal composition 1′ obtained from the removal of only the freezing point depressant 1 from the liquid crystal composition 1 was also confirmed in the same manner. It was confirmed that the phase transition from the crystal to the smectic phase was carried out at around 91° C., the phase changed to the nematic phase at around 136° C., and the nematic phase was maintained up to around 200° C. in a temperature decrease in a case of a temperature increase to 200° C.

The phase transition temperature of the liquid crystal composition 1 from the smectic phase to the nematic phase is defined as T1 (SN), and the phase transition temperature of the liquid crystal composition 1′ from the smectic phase to the nematic phase is defined as T1′ (SN).

(Evaluation Standard)

Ti(SN)−T1′(SN)≥−3 A:

−3 >T1(SN)−T1′(SN)≥−10 B:

−10 >T1(SN)−T1′(SN) C:

<Alignment Defects>

For the manufactured optically anisotropic layer 1, observation with a polarization microscope and visual observation of a laminate obtained by inserting the optically anisotropic layer 1 between two polarizing plates arranged in the state of crossed nicols were each performed, and the defects of the optically anisotropic layer 1 were evaluated according to the following standard.

(Evaluation Standard)

A: By observation with the polarization microscope, disturbance of a liquid crystal director can hardly be confirmed.

B: By observation with the polarization microscope, disturbance of a liquid crystal director can be slightly confirmed, but by visual observation, defects caused by misalignment cannot be confirmed.

C: By visual observation, defects caused by misalignment can be confirmed, which is unacceptable.

<X-Ray Diffraction Measurement>

For the optically anisotropic layer 1 formed on the surface of the photo-alignment film 1, X-ray diffraction measurement was performed under the following equipment and conditions, and it was confirmed whether diffracted light derived from the order (periodic structure) of the smectic phase was observed.

As a result, in the optically anisotropic layer 1, a peak showing a periodic structure was observed at 20=2.1° and diffracted light derived from the order of the smectic phase was confirmed.

(Apparatus and Conditions)

X-ray diffractometer ATXG (model name, for evaluation of a thin film structure, manufactured by Rigaku), Cu source (50 kV·300 mA), 0.45 solar slit

### Examples 2 to 9

Optically anisotropic layers 2 to 9 of Examples 2 to 9 were manufactured by the same method as in Example 1, except that the liquid crystal compound and the freezing point depressant shown in Table 4 below were used instead of the liquid crystal compounds R1 and R2, and the freezing point depressant A1 included in the liquid crystal composition 1, and each evaluation was performed.

### Example 10

A light absorption anisotropic layer 10 of Example 10 was manufactured by the same method as in Example 1, except that the following liquid crystal composition 10 was used instead of the liquid crystal composition 1, and each evaluation was performed.

Liquid crystal composition 10

| | |
|---|---|
| The following liquid crystal compound R5 | 100.00 parts by mass |
| The following dichroic coloring agent D1 | 1.00 part by mass |
| The following dichroic coloring agent D2 | 1.00 part by mass |
| The following dichroic coloring agent D3 | 1.00 part by mass |
| The following freezing point depressant A6 | 10.00 parts by mass |
| The polymerization initiator S1 | 0.50 parts by mass |
| The leveling agent P1 | 0.23 parts by mass |
| Cyclopentanone | 292.45 parts by mass |

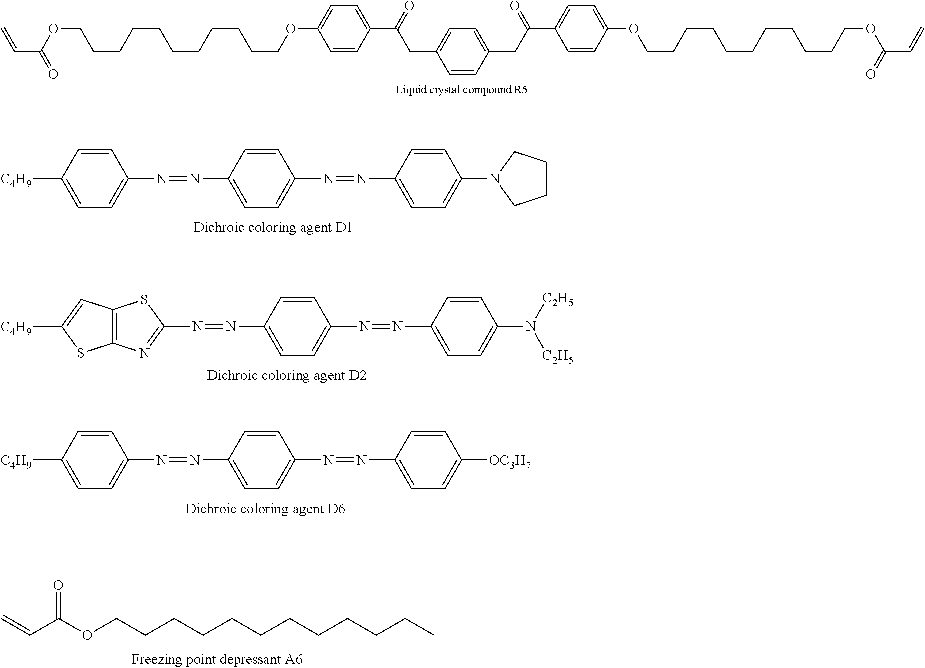

### Comparative Examples 1 to 8

Optically anisotropic layers C1 to C8 of Comparative Examples 1 to 8 were manufactured by the same method as in Example 1, except that the liquid crystal compounds and the freezing point depressant shown in Table 4 below were used instead of the liquid crystal compounds R1 and R2 included in the liquid crystal composition 1, and the freezing point depressant A1, and each evaluation was performed.

[Evaluation Results]

Table 4 below shows each evaluation result of the compositions and the phase transition temperatures of the liquid crystal compositions used for formation of the optically anisotropic layer in Examples 1 to 10 and Comparative Examples 1 to 8 (referred to as a light absorption anisotropic layer in Example 10; the same applies hereinafter), and the alignment defects of an optically anisotropic layer thus formed.

Furthermore, it was confirmed that in a case where the phase difference was measured for the optically anisotropic layers 1 to 10 and C1 to C8 formed in Examples 1 to 10 and Comparative Examples 1 to 8, the in-plane retardation Re1(550) was 110 to 150 nm, and the both were positive A plates.

TABLE 4

| | Liquid crystal compound | | | | | Freezing point depressant | | | | |
|---|---|---|---|---|---|---|---|---|---|---|
| | | I/O value | | | | | | Addition | Evaluation | |
| | | Mesogen | Spacer | | | | I/O | amount | Phase | |
| | | group | group | | | | value | parts by | transition | Alignment |
| | Type | Am | As | \|Am − As\| | (Am + As)/2 | Type | Aa | mass | temperature | defects |
| Example 1 | R1 | 0.42 | 0.68 | 0.26 | 0.55 | A1 | 1.52 | 10 | A | A |
| | R2 | | | | | | | | | |
| Example 2 | R1 | 0.42 | 0.68 | 0.26 | 0.55 | A2 | 1.63 | 10 | A | A |
| | R2 | | | | | | | | | |
| Example 3 | R1 | 0.42 | 0.68 | 0.26 | 0.55 | A3 | 0.70 | 10 | A | A |
| | R2 | | | | | | | | | |
| Example 4 | R1 | 0.42 | 0.68 | 0.26 | 0.55 | A4 | 0.62 | 10 | A | A |
| | R2 | | | | | | | | | |
| Example 5 | R1 | 0.42 | 0.68 | 0.26 | 0.55 | A4 | 0.62 | 0.1 | A | B |
| | R2 | | | | | | | | | |
| Example 6 | R1 | 0.42 | 0.68 | 0.26 | 0.55 | A4 | 0.62 | 35 | B | B |
| | R2 | | | | | | | | | |
| Example 7 | R3 | 0.63 | 1.42 | 0.80 | 1.02 | A1 | 1.52 | 10 | A | A |
| Example 8 | R4 | 0.61 | 0.27 | 0.33 | 0.44 | A5 | 0.21 | 10 | A | A |
| Example 9 | R5 | 0.50 | 0.27 | 0.23 | 0.39 | A5 | 0.21 | 10 | A | A |
| Example 10 | R5 | 0.50 | 0.27 | 0.23 | 0.39 | A5 | 0.21 | 10 | A | A |
| Comparative | R1 | 0.42 | 0.68 | 0.26 | 0.55 | A6 | 0.46 | 10 | C | C |
| Example 1 | | | | | | | | | | |
| Comparative | R1 | 0.42 | 0.68 | 0.26 | 0.55 | A5 | 0.21 | 10 | C | C |
| Example 2 | | | | | | | | | | |
| Comparative | R6 | 0.54 | 0.70 | 0.16 | 0.62 | A1 | 1.52 | 10 | C | C |
| Example 3 | | | | | | | | | | |
| Comparative | R6 | 0.54 | 0.70 | 0.16 | 0.62 | A2 | 1.63 | 10 | C | C |
| Example 4 | | | | | | | | | | |
| Comparative | R6 | 0.54 | 0.70 | 0.16 | 0.62 | A7 | 0.51 | 10 | C | C |
| Example 5 | | | | | | | | | | |
| Comparative | R5 | 0.50 | 0.27 | 0.23 | 0.39 | A8 | 0.41 | 5 | C | C |
| Example 6 | | | | | | | | | | |
| Comparative | R7 | 0.37 | 1.42 | 1.05 | 0.90 | A9 | 0.62 | 10 | C | C |
| Example 7 | | | | | | | | | | |
| Comparative | R7 | 0.37 | 1.42 | 1.05 | 0.90 | A3 | 0.70 | 10 | C | C |
| Example 8 | | | | | | | | | | |

The structures of the liquid crystal compounds and the freezing point depressants in Table 4 are shown below.

In addition, the above-mentioned liquid crystal composition L was prepared using this liquid crystal compound, and the values of Re(450)/Re(550) of the optically anisotropic layers manufactured by the above-mentioned method are shown below.

In addition, the molar absorption coefficient of this freezing point depressant at a wavelength of 350 to 750 nm is shown below.

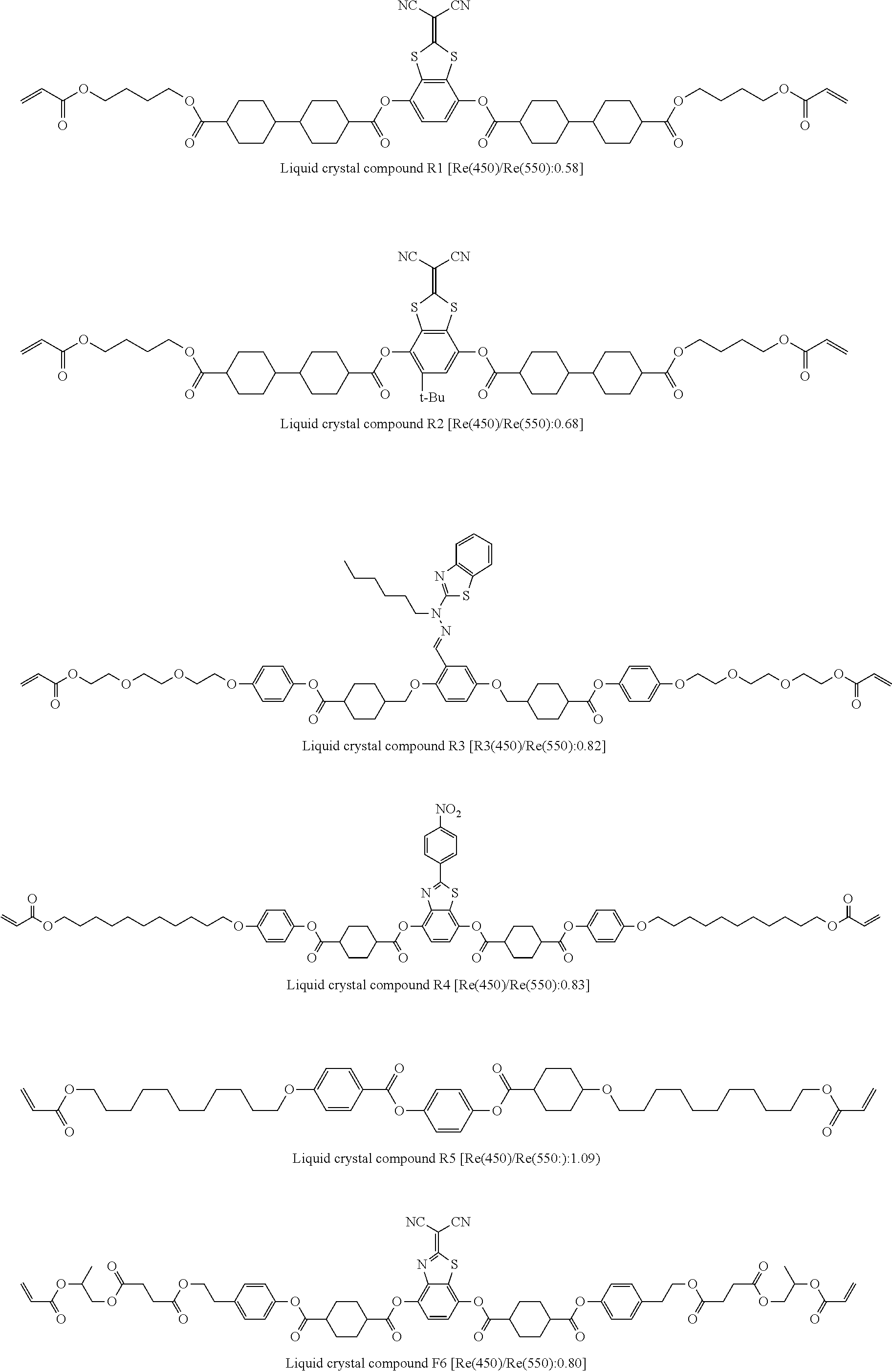

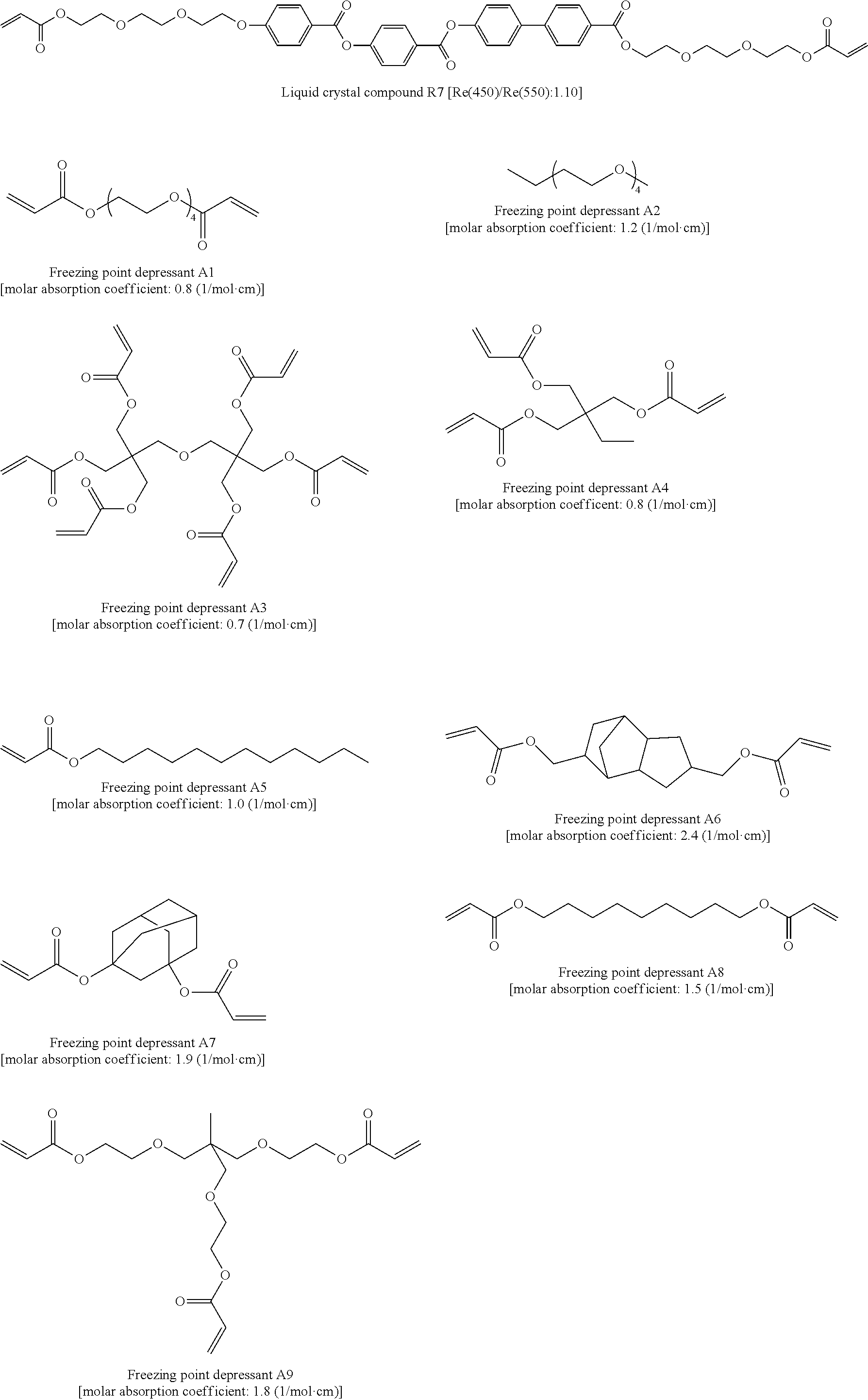

From the results shown in Table 4 above, it was found that in a case where a liquid crystal composition which does not satisfy any one or both of Expression (1) and Expression (2-1) or (2-2) is used, a decrease in a phase transition temperature from the smectic phase to the nematic phase cannot be suppressed, and the alignment defects in a liquid crystal cured layer thus formed cannot be suppressed (Comparative Examples 1 to 8).

SP1-MG-SP2 (I)

|Am−As|≥0.2 (1)

In a case of Am≤As,Aa≥(Am+As)/2 (2-1)

In a case of Am>As,Aa≤(Am+As)/2 (2-2)

In contrast, it was found that in a case where a liquid crystal composition satisfying Expression (1) and Expression (2-1) or (2-2) is used, a decrease in phase transition temperature from a smectic phase to a nematic phase is suppressed, and alignment defects in a liquid crystal cured layer thus formed can be suppressed (Examples 1 to 10).

In addition, from the results of Examples 4 to 6, it was found that in a case where the content of the freezing point depressant is 1 to 30 parts by mass with respect to 100 parts by mass of the liquid crystal compound, alignment defects in a liquid crystal cured layer thus formed can be further suppressed.

### EXPLANATION OF REFERENCES

10: optical film
12: liquid crystal cured layer
14: alignment film
16: support

What is claimed is:

1. A liquid crystal composition comprising:
a liquid crystal compound exhibiting a smectic phase; and
a freezing point depressant,
wherein the liquid crystal compound is a compound represented by Formula (I) and the liquid crystal composition satisfies Expression (1) and Expression (2-1) or (2-2),
SP1-MG-SP2 (I)
in Formula (I),
SP1 and SP2 each independently represent a spacer group, and
MG represents a mesogen group,

|Am−As|≥0.2 (1)
in a case of Am≤As,Aa≥(Am+As)/2 (2-1),
in a case of Am>As,Aa≤(Am+As)/2 (2-2),
in Expressions (1), (2-1), and (2-2),
Am represents an I/O value of the mesogen group of the liquid crystal compound,
As represents an I/O value of the spacer group of the liquid crystal compound, provided that in a case where structures of SP1 and SP2 in Formula (I) are different from each other, with Am≤As, As represents an I/O value of a spacer group having a larger I/O value, and with Am >As, As represents an I/O value of a spacer group having a smaller I/O value, and
Aa represents an I/O value of the freezing point depressant.

2. The liquid crystal composition according to claim 1,
wherein the freezing point depressant is a non-liquid crystal compound.

3. The liquid crystal composition according to claim 1,
wherein a content of the freezing point depressant is 1 to 30 parts by mass with respect to 100 parts by mass of the liquid crystal compound.

4. The liquid crystal composition according to claim 1,
wherein the freezing point depressant has a molecular weight of 2,000 or less.

5. The liquid crystal composition according to claim 1,
wherein the freezing point depressant has a polymerizable group.

6. The liquid crystal composition according to claim 1,
wherein a molar absorption coefficient of the freezing point depressant at a wavelength of 350 to 750 nm is 100 (1/mol·cm) or less.

7. The liquid crystal composition according to claim 1,
wherein an optically anisotropic layer manufactured using the liquid crystal compound satisfies Expression (3),
Re(450)/Re(550)>1.0 (3)
in Expression (3), Re(450) represents an in-plane retardation of the optically anisotropic layer at a wavelength of 450 nm and Re(550) represents an in-plane retardation of the optically anisotropic layer at a wavelength of 550 nm.

8. The liquid crystal composition according to claim 1,
wherein an optically anisotropic layer manufactured using the liquid crystal compound satisfies Expression (4),
Re(450)/Re(550)≤1.0 (4)
in Expression (4), Re(450) represents an in-plane retardation of the optically anisotropic layer at a wavelength of 450 nm and Re(550) represents an in-plane retardation of the optically anisotropic layer at a wavelength of 550 nm.

9. The liquid crystal composition according to claim 1,
wherein the liquid crystal compound is a compound represented by Formula (II),
P¹-L¹-D⁵-(A¹)ₐ₁-D³-(G¹)_{g1}-D¹-[Ar-D²]_{q1}-(G²)_{g2}-D⁴-(A²)ₐ₂-D⁶- L²-P² (II)
in Formula (II),
a1, a2, g1, and g2 each independently represent 0 or 1, provided that at least one of a1 or g1 represents 1, and at least one of a2 or g2 represents 1,
q1 represents 1 or 2,
D¹, D², D³, D⁴, D⁵, and D⁶ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms, provided that in a case where q1 is 2, a plurality of D²'s may be the same as or different from each other,
G¹ and G² each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be substituted with —O—, —S—, or —NH—,
A¹ and A² each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be substituted with —O—, —S—, or —NH—,
L¹ and L² each independently represent a single bond, a linear or branched alkylene group having 1 to 14 carbon atoms, or a divalent linking group in which one or more of —CH₂-'s constituting the linear or branched alkylene group having 1 to 14 carbon atoms are substituted with —O—, —S—, —NH—, —N(Q)-, or —CO—, where Q represents a substituent,
P¹ and P² each independently represent a monovalent organic group, where at least one of P¹ or P² represents a polymerizable group, and
Ar represents an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be substituted with —O—, —S—, or —NH—, provided that in a case where q¹ is 2, a plurality of Ar's may be the same as or different from each other.

10. The liquid crystal composition according to claim 9,
wherein Ar in Formula (II) represents any aromatic ring selected from the group consisting of groups represented by Formulae (Ar-1) to (Ar-7), 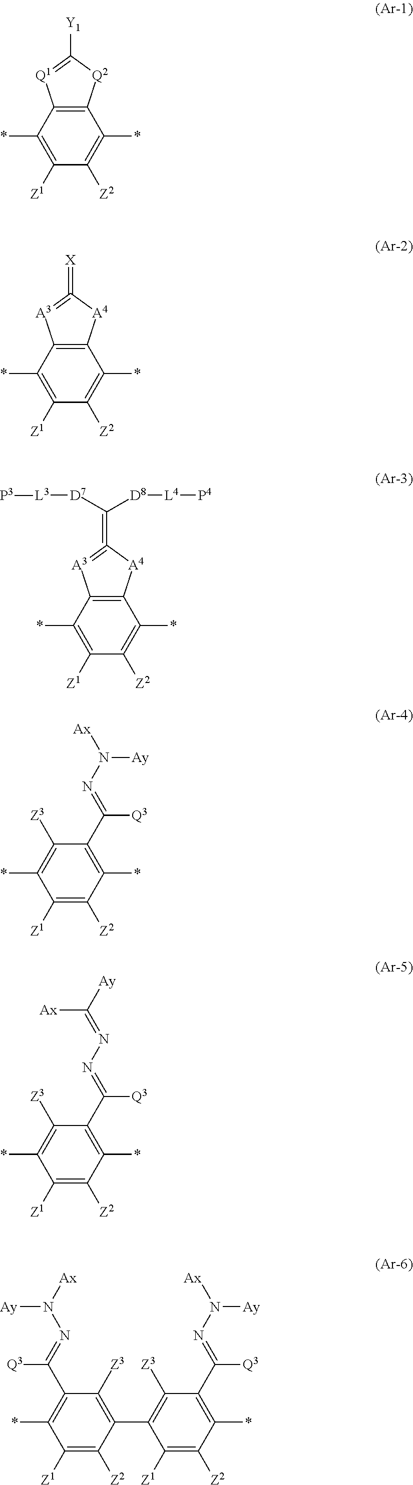 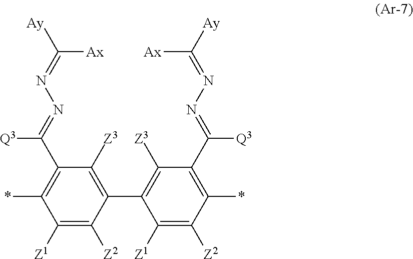
in Formulae (Ar-1) to (Ar-7),
* represents a bonding position to D¹ or D²,
Q¹ represents N or CH,
Q² represents —S—, —O—, or —N(R⁶)—, where R⁶ represents a hydrogen atom or an alkyl group having 1 to 6 carbon atoms,
Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, where one or more of —CH₂-'s constituting the alicyclic hydrocarbon group may be substituted with —O—, —S—, or —NH—,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —N⁸R⁹, —SR¹⁰, —COOR¹¹, or —COR¹², where R⁷ to R¹² each independently represent a hydrogen atom or an alkyl group having 1 to 6 carbon atoms, and Z¹ and Z² may be bonded to each other to form an aromatic ring,
A³ and A⁴ each independently represent a group selected from the group consisting of —O—, —N(R¹³)—, —S—, and —CO—, where R¹³ represents a hydrogen atom or a substituent,
X represents a hydrogen atom or a non-metal atom of Groups XIV to XVI to which a substituent may be bonded,
D⁷ and D⁸ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms,
L³ and L⁴ each independently represent a single bond, a linear or branched alkylene group having 1 to 14 carbon atoms, or a divalent linking group in which one or more of —CH₂-'s constituting the linear or branched alkylene group having 1 to 14 carbon atoms are substituted with —O—, —S—, —NH—, —N(Q)-, or —CO—, where Q represents a substituent,
P³ and P⁴ each independently represent a monovalent organic group, where at least one of P³ or P⁴, or P¹ or P² in Formula (II) represents a polymerizable group,
Ax represents an organic group having 2 to 30 carbon atoms, which has at least one aromatic ring selected from the group consisting of an aromatic hydrocarbon ring and an aromatic heterocyclic ring,
Ay represents a hydrogen atom, an alkyl group having 1 to 12 carbon atoms, which may have a substituent, or an organic group having 2 to 30 carbon atoms, which has at least one aromatic ring selected from the group consisting of an aromatic hydrocarbon ring and an aromatic heterocyclic ring,
the aromatic ring in each of Ax and Ay may have a substituent, and Ax and Ay may be bonded to each other to form a ring, and
Q³ represents a hydrogen atom or an alkyl group having 1 to 20 carbon atoms, which may have a substituent.

11. The liquid crystal composition according to claim 1, further comprising a dichroic substance.

12. A liquid crystal cured layer obtained by immobilizing an alignment state of the liquid crystal composition according to claim 1.

13. The liquid crystal cured layer according to claim 12,
wherein the liquid crystal cured layer exhibits a diffraction peak derived from a periodic structure in X-ray diffraction measurement.

14. A liquid crystal cured layer obtained by immobilizing an alignment state of the liquid crystal composition according to claim 2,
wherein the liquid crystal cured layer exhibits a diffraction peak derived from a periodic structure in X-ray diffraction measurement.

15. The liquid crystal cured layer according to claim 12,
wherein the liquid crystal compound included in the polymerizable liquid crystal composition is immobilized in a state of being horizontally aligned with respect to a main surface of an optically anisotropic layer.

16. The liquid crystal cured layer according to claim 12,
wherein the liquid crystal cured layer is a positive A plate.

17. The liquid crystal cured layer according to claim 12,
wherein the liquid crystal cured layer is a polarizer.

18. An optical film comprising the liquid crystal cured layer according to claim 12.

19. The optical film according to claim 18,
wherein the liquid crystal cured layer is formed on a surface of a photo-alignment film.

20. A polarizing plate comprising:
a liquid crystal cured layer obtained by immobilizing an alignment state of the liquid crystal composition according to claim 1; and
a polarizer.

21. A polarizing plate comprising:
a phase difference film; and
a liquid crystal cured layer obtained by immobilizing an alignment state of the liquid crystal composition according to claim 11.

22. A polarizing plate comprising:
a liquid crystal cured layer obtained by immobilizing an alignment state of the liquid crystal composition according to claim 1; and
a liquid crystal cured layer obtained by immobilizing an alignment state of the liquid crystal composition according to claim 11.

23. An image display device comprising:
the optical film according to claim 18.

24. The image display device according to claim 23,
wherein the image display device is a liquid crystal display device.

25. The image display device according to claim 23,
wherein the image display device is an organic EL display device.

26. A method for suppressing crystallization while suppressing a decrease in phase transition temperature of a liquid crystal compound from a smectic phase to a nematic phase, by mixing the liquid crystal compound exhibiting smectic properties with a freezing point depressant,
wherein the liquid crystal compound is a compound represented by Formula (I), and
the freezing point depressant is mixed with the liquid crystal compound to satisfy Expression (1) and Expression (2-1) or (2-2),
SP1-MG-SP2 (I)
in Formula (I),
SP1 and SP2 each independently represent a spacer group,
MG represents a mesogen group,

|Am−As|≥0.2 (1)
in a case of Am≤As,Aa≥(Am+As)/2 (2-1),
in a case of Am>As,Aa≤(Am+As)/2 (2-2),
Here, in Expressions (1), (2-1), and (2-2),
Am represents an I/O value of the mesogen group of the liquid crystal compound,
As represents an I/O value of the spacer group of the liquid crystal compound, provided that in a case where structures of SP1 and SP2 in Formula (I) are different from each other, with Am≤As, As represents an I/O value of a spacer group having a larger I/O value, and with Am>As, As represents an I/O value of a spacer group having a smaller I/O value, and
Aa represents an I/O value of the freezing point depressant.
